(19) United States
(12) Patent Application Publication
(10) Pub. No.: US 2026/0255795 A1
(43) Pub. Date: Aug. 27, 2026

(54) DISPLAY DEVICE AND ELECTRONIC DEVICE INCLUDING THE SAME

(71) Applicant: Samsung Display Co., Ltd., Yongin-Si (KR)

(72) Inventors: Hey Jin SHIN, Yongin-si (KR); Dae Hyun KIM, Yongin-si (KR); Sung Hwan KIM, Yongin-si (KR); Hyun Ae PARK, Yongin-si (KR); Jong Min LEE, Yongin-si (KR); Chang Kyu JIN, Yongin-si (KR)

(21) Appl. No.: 19/336,502

(22) Filed: Sep. 23, 2025

(30) Foreign Application Priority Data
Feb. 21, 2025 (KR) 10-2025-0022652

(51) Int. Cl. H10K 59/121; H10K 59/131

(52) U.S. Cl. CPC H10K 59/1213; H10K 59/131

(57) ABSTRACT

A display device includes a substrate, a circuit layer disposed on the substrate and comprising a light emitting pixel driver, and a light emitting element layer disposed on the circuit layer and including a light emitting element electrically connected to the light emitting pixel driver. The light emitting pixel driver includes a first transistor including a gate electrode included in a third gate conductive layer, a channel, a first electrode and a second electrode included in a second semiconductor layer, and a gate additional electrode overlapping the channel, and a second transistor including a gate electrode included in the third gate conductive layer, a channel, a first electrode and a second electrode included in the second semiconductor layer, and a gate additional electrode overlapping the channel. The gate additional electrode of the first transistor is disposed on a same layer as the gate additional electrode of the second transistor.

### CROSS-REFERENCE TO RELATED APPLICATION

This application claims priority under 35 U.S.C. § 119 to Korean Patent Application No. 10-2025-0022652 filed on Feb. 21, 2025, in the Korean Intellectual Property Office, the contents of which in its entirety are incorporated herein by reference.

### BACKGROUND

### 1. Technical Field

The present disclosure relates to a display device and an electronic device including the same.

### 2. Description of the Related Art

With the advance of information-oriented society, the demand for display devices for displaying image has increased in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer containing an organic light emitting material. The organic light emitting display device implements the image display using a self-light emitting element, and thus may have relatively superior performance in power consumption, response speed, luminous efficiency, brightness, and wide viewing angle compared to other display devices.

In the display device, a display surface from which light is emitted may include a display area in which an image is displayed, and a non-display area around the display area. Emission areas emitting light with respective luminance and colors may be arranged in the display area.

### SUMMARY

Aspects of the present disclosure provide a display device with improved transistor characteristics and an electronic device including the same.

Aspects of the present disclosure also provide a display device with improved integration density and an electronic device including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device comprises a substrate, a circuit layer disposed on the substrate and including a light emitting pixel driver, and a light emitting element layer disposed on the circuit layer and including a light emitting element electrically connected to the light emitting pixel driver. The circuit layer includes a first semiconductor layer, a first gate conductive layer disposed on the first semiconductor layer, a second gate conductive layer disposed on the first gate conductive layer, a lower gate conductive layer disposed on the second gate conductive layer, a second semiconductor layer disposed on the lower gate conductive layer, and a third gate conductive layer disposed on the second semiconductor layer. The light emitting pixel driver includes a first transistor including a gate electrode included in the third gate conductive layer, a channel portion, a first electrode and a second electrode included in the second semiconductor layer, and a gate additional electrode overlapping the channel portion, and a second transistor including a gate electrode electrically connected to the gate electrode of the first transistor and included in the third gate conductive layer, a channel portion, a first electrode and a second electrode included in the second semiconductor layer, and a gate additional electrode overlapping the channel portion. The gate additional electrode of the first transistor is disposed on a same layer as the gate additional electrode of the second transistor.

In an embodiment, the circuit layer further may comprise a first source-drain conductive layer disposed on the third gate conductive layer. The gate additional electrode of the first transistor may be connected to the second electrode of the first transistor through a first contact hole, and the gate additional electrode of the second transistor may be connected to the gate electrode of the second transistor through a second contact hole. The first contact hole may extend from the first source-drain conductive layer to the lower gate conductive layer, and the second contact hole may extend from the third gate conductive layer to the lower gate conductive layer.

In an embodiment, a depth of the first contact hole may be greater than a depth of the second contact hole.

In an embodiment, an area of the first contact hole in a plan view may be larger than an area of the second contact hole in the plan view.

In an embodiment, the light emitting pixel driver may further comprise a third transistor comprising a gate electrode included in the third gate conductive layer, a channel portion, a first electrode and a second electrode included in the second semiconductor layer, and a gate additional electrode overlapping the channel portion. The gate additional electrode of the third transistor may be disposed on the same layer as the gate additional electrode of the first transistor and the gate additional electrode of the second transistor.

In an embodiment, the light emitting pixel driver may further comprise a fourth transistor including a first electrode, a second electrode and a channel portion electrically connected to the second electrode of the first transistor and included in the second semiconductor layer, a gate electrode included in the third gate conductive layer, and a gate additional electrode overlapping the channel portion. The gate additional electrode of the fourth transistor may be disposed below the gate additional electrode of the second transistor.

In an embodiment, a distance between the gate additional electrode of the second transistor and the channel portion of the second transistor may be less than a distance between the gate additional electrode of the fourth transistor and the channel portion of the fourth transistor.

In an embodiment, the gate additional electrode of the second transistor may be connected to the gate electrode of the second transistor through a second contact hole, and the gate additional electrode of the fourth transistor may be connected to the gate electrode of the fourth transistor through a third contact hole. A depth of the second contact hole may be less than a depth of the third contact hole.

In an embodiment, an area of the second contact hole in a plan view may be smaller than an area of the third contact hole in the plan view.

In an embodiment, the light emitting pixel driver may further comprise a sixth transistor including a first electrode, a second electrode and a channel portion connected between the second electrode of the first transistor and the first electrode of the fourth transistor and included in the second semiconductor layer, a gate electrode included in the third gate conductive layer, and a gate additional electrode overlapping the channel portion. The gate additional electrode of the sixth transistor may be disposed on the same layer as the gate additional electrode of the fourth transistor.

In an embodiment, the light emitting pixel driver may further comprise a fifth transistor including a first electrode, a second electrode and a channel portion electrically connected to the first electrode of the first transistor and included in the first semiconductor layer, and a gate electrode included in the first gate conductive layer.

In an embodiment, the gate additional electrode of the second transistor may be disposed on a layer different from the gate electrode of the fifth transistor.

In an embodiment, the light emitting pixel driver may further comprise a first capacitor including a second capacitor electrode electrically connected to the second electrode of the first transistor and included in the second gate conductive layer, and a first capacitor electrode overlapping the second capacitor electrode and included in the first gate conductive layer.

In an embodiment, the gate additional electrode of the second transistor may be disposed on a layer different from the first capacitor electrode and the second capacitor electrode of the first capacitor.

In an embodiment, the light emitting pixel driver may further comprise a second capacitor including a third capacitor electrode electrically connected to the second electrode of the first transistor and included in the second gate conductive layer, and a fourth capacitor electrode overlapping the third capacitor electrode and included in the first gate conductive layer.

In an embodiment, the gate additional electrode of the second transistor may be disposed on a layer different from the third capacitor electrode and the fourth capacitor electrode of the second capacitor.

In an embodiment, the light emitting pixel driver may further comprise a seventh transistor including a first electrode, a second electrode and a channel portion electrically connected to the fourth capacitor electrode of the second capacitor and included in the second semiconductor layer, and a gate electrode included in the third gate conductive layer.

In an embodiment, the light emitting pixel driver may further comprise a fourth transistor including a first electrode, a second electrode and a channel portion electrically connected to the second electrode of the first transistor and included in the second semiconductor layer, a gate electrode included in the third gate conductive layer, and a gate additional electrode overlapping the channel portion. The gate additional electrode of the fourth transistor may be disposed on the same layer as the gate additional electrode of the second transistor.

In an embodiment, the light emitting pixel driver may further comprise a sixth transistor including a first electrode, a second electrode and a channel portion connected between the second electrode of the first transistor and the first electrode of the fourth transistor and included in the second semiconductor layer, a gate electrode included in the third gate conductive layer, and a gate additional electrode overlapping the channel portion. The gate additional electrode of the sixth transistor may be disposed on the same layer as the gate additional electrode of the fourth transistor.

According to an embodiment of the present disclosure, an electronic device comprises a display device displaying an image, a lower cover located below the display device, and a cover window located on the display device. The display device includes a substrate, a circuit layer disposed on the substrate and including a light emitting pixel driver, and a light emitting element layer disposed on the circuit layer and including light emitting elements electrically connected to the light emitting pixel driver. The circuit layer includes a first semiconductor layer, a first gate conductive layer disposed on the first semiconductor layer, a second gate conductive layer disposed on the first gate conductive layer, a lower gate conductive layer disposed on the second gate conductive layer, a second semiconductor layer disposed on the lower gate conductive layer, and a third gate conductive layer disposed on the second semiconductor layer. The light emitting pixel driver includes a first transistor including a gate electrode included in the third gate conductive layer, a channel portion, a first electrode and a second electrode included in the second semiconductor layer, and a gate additional electrode overlapping the channel portion, and a second transistor including a gate electrode electrically connected to the gate electrode of the first transistor and included in the third gate conductive layer, a channel portion, a first electrode and a second electrode included in the second semiconductor layer, and a gate additional electrode overlapping the channel portion. The gate additional electrode of the first transistor is disposed on a same layer as the gate additional electrode of the second transistor.

The display device and the electronic device including the same according to an embodiment of the present disclosure may have improved transistor characteristics.

The display device and the electronic device including the same according to an embodiment of the present disclosure may have an improved integration density.

It should be noted that effects and features of the present disclosure are not limited to those described above and other effects and features of the present disclosure will be apparent to those skilled in the art from the following descriptions.

### BRIEF DESCRIPTION OF THE DRAWINGS

The above and other aspects and features of the present disclosure will become apparent and readily appreciated from the following description of the embodiment, taken in conjunction with the accompanying drawings.

FIG. 1 is a perspective view illustrating an electronic device according to an embodiment.

FIG. 2 is an exploded perspective view of the electronic device shown in FIG. 1.

FIG. 3 is a plan view illustrating the display device of FIG. 2.

FIG. 4 is a cross-sectional view taken along a line A-A′ of FIG. 3.

FIG. 5 is an enlarged view illustrating part B of FIG. 3.

FIG. 6 is a block diagram illustrating the display device of FIG. 2.

FIG. 7 is an equivalent circuit diagram illustrating the light emitting pixel driver according to an embodiment.

FIG. 8 is a plan view illustrating a display panel and a display driving circuit according to one embodiment.

FIG. 9 is a plan view illustrating a circuit layer of part C of FIG. 8.

FIG. 10 is a plan view illustrating a circuit layer of part D of FIG. 8.

FIG. 11 is a cross-sectional view illustrating a first transistor, a fifth transistor, a sixth transistor, a first capacitor, a second capacitor, and a light emitting element of FIG. 7.

FIG. 12 is a layout diagram illustrating a circuit layer of part E of FIG. 10.

FIG. 13 is a layout diagram illustrating a lower conductive layer of the circuit layer according to an embodiment.

FIG. 14 is a layout diagram illustrating a first semiconductor layer of the circuit layer according to an embodiment.

FIG. 15 is a layout diagram illustrating a first gate conductive layer of the circuit layer according to an embodiment.

FIG. 16 is a layout diagram illustrating a second gate conductive layer of the circuit layer according to an embodiment.

FIG. 17 is a layout diagram illustrating a lower gate conductive layer of the circuit layer according to an embodiment.

FIG. 18 is a layout diagram illustrating a second semiconductor layer of the circuit layer according to an embodiment.

FIG. 19 is a layout diagram illustrating a gate contact hole group and a third gate conductive layer of the circuit layer according to an embodiment.

FIG. 20 is a layout diagram illustrating a gate contact hole group, a first contact hole group, a second contact hole group, and a first source-drain conductive layer of the circuit layer according to an embodiment.

FIG. 21 is a layout diagram illustrating a first via hole group and a second source-drain conductive layer of the circuit layer according to an embodiment.

FIG. 22 is a layout diagram illustrating a second via hole group, an anode electrode, and a pixel defining layer according to an embodiment.

FIG. 23 is a cross-sectional view taken along lines F-F′, G-G′, and H-H′ of FIGS. 13 to 19.

FIG. 24 is a cross-sectional view illustrating cross-sections of a second transistor, a third transistor, a fourth transistor, and a sixth transistor of a display device according to an embodiment.

### DETAILED DESCRIPTION OF THE EMBODIMENTS

The embodiments will now be described more fully hereinafter with reference to the accompanying drawings. The embodiments may, however, be implemented in different forms and should not be construed as being limited to the embodiments set forth herein. Rather, these embodiments are merely provided to ensure the full disclosure of the present inventive concept and to completely convey the scope of the present disclosure to those skilled in the art.

It will also be understood that when a layer is referred to as being “on” another layer or substrate, the layer may not only be directly on another layer or substrate, but also be indirectly on another layer or substrate with intervening layers therebetween. The same reference numbers may indicate the same components throughout the specification.

Hereinafter, embodiments of the present disclosure will be described in detail with reference to the accompanying drawings.

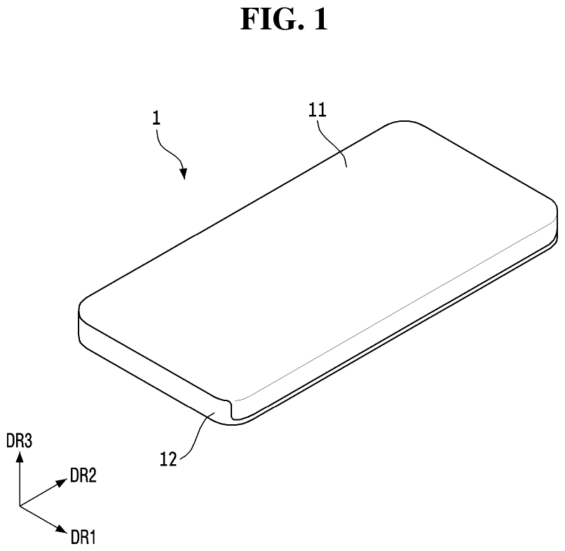

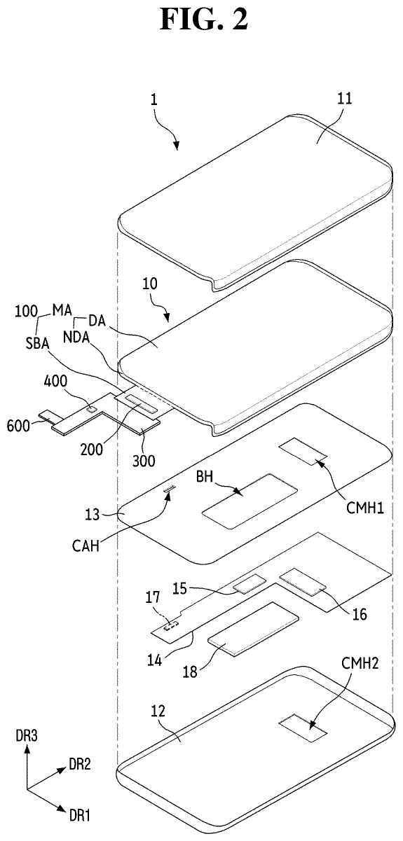

FIG. 1 is a perspective view illustrating an electronic device according to an embodiment. FIG. 2 is an exploded perspective view of the electronic device shown in FIG. 1.

Referring to FIGS. 1 and 2, an electronic device 1 according to an embodiment may display an image in a display area. The electronic device 1 may provide portability. For example, the electronic device 1 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 1 according to an embodiment is not limited to a portable electronic device, and may be a large-sized device such as a television, a laptop computer, a monitor, a billboard, and an Internet-of-Things (IoT) device.

The electronic device 1 according to an embodiment may include a display device 10, and a cover window 11 and a lower cover 12, which are provided as a housing to protect the display device 10. The electronic device 1 may further include a bracket 13 located between the display device 10 and a main circuit board 14.

The electronic device 1 may have a shape close to a rectangular shape in a plan view. For example, the electronic device 1 may have a rectangular shape, in a plan view, having short sides in a first direction DR1 and long sides in a second direction DR2. A corner where the short side in the first direction DR1 and the long side in the second direction DR2 meet may be right-angled or rounded with a predetermined curvature. However, the planar shape of the electronic device 1 is not limited to the rectangular shape, and may be formed in a polygonal shape, a circular shape or an elliptical shape.

In the drawings, the first direction DR1 and the second direction DR2 cross each other and represent horizontal directions. For example, the first direction DR1 and the second direction DR2 may be orthogonal to each other. In addition, a third direction DR3 crosses the first direction DR1 and the second direction DR2, and may represent, for example, a perpendicular direction orthogonal to the horizontal directions. Unless defined otherwise, in the present disclosure, directions indicated by arrows of the first to third directions DR1, DR2, and DR3 may be referred to as one side, and the opposite directions thereto may be referred to as the other side. Also, the terms, such as “above,” “upper side,” “upper portion,” “top,” and “top surface,” as used herein may refer to a direction indicated by an arrow of the third direction DR3, and the terms, such as “below,” “lower side,” “lower portion,” “bottom,” and “bottom surface,” as used herein may refer to a direction opposite to the direction of the third direction DR3.

The cover window 11 may be located on the display device 10 to cover the top surface of the display device 10. The cover window 11 may serve to protect the top surface of the display device 10.

The cover window 11 may include a light transmitting portion that is transparent and a light blocking portion that is opaque. The light transmitting portion may overlap a display area DA of the display device 10 in the third direction DR3, and the light blocking portion may overlap a non-display area NDA of the display device 10 in the third direction DR3.

The cover window 11 may include a top surface portion corresponding to the top surface of the electronic device 1, a left surface portion corresponding to the left side surface of the electronic device 1, and a right surface portion corresponding to the right side surface of the electronic device 1. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion. The light transmitting portion of the cover window 11 may be located on most of each of the top, left, and right surface portions of the cover window 11. The light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 10 may be located below the cover window 11. That is, the cover window 11 may be located on the display device 10.

The display device 10 may include a top surface portion facing the top surface portion of the cover window 11, a left surface portion facing the left surface portion of the cover window 11, and a right surface portion facing the right surface portion of the cover window 11. The left surface portion of the display device 10 may extend from the left side of the top surface portion, and the right surface portion of the display device 10 may extend from the right side of the top surface portion.

The display device 10 may include a display panel 100. The display panel 100 may include a main region MA including the display area DA where an image is displayed and the non-display area NDA around the display area DA, and a sub-region SBA protruding from one side of the main region MA.

The display area DA may occupy most of the main region MA. The display area DA may be located at the center of the main region MA. In other words, each of the top, left, and right surface portions of the display device 10 may include the display area DA and the non-display area NDA. The display area DA may occupy most of each of the top, left, and right surface portions of the display device 10.

The non-display area NDA may be located outside the display area DA. The non-display area NDA may be an edge area of the main region MA. The non-display area NDA may be located at the upper edge and lower edge of the top surface portion of the display device 10, the upper edge, left edge, and lower edge of the left surface portion of the display device 10, and the upper edge, right edge, and lower edge of the right surface portion of the display device 10.

The sub-region SBA may protrude from one side of the main region MA in the second direction DR2. The length of the sub-region SBA in the first direction DR1 may be less than or equal to the length of the main region MA in the first direction DR1. The length of the sub-region SBA in the second direction DR2 may be less than the length of the main region MA in the second direction DR2, but is not limited thereto. Since a part of the sub-region SBA may be bent, another part of the sub-region SBA may overlap the main region MA in the third direction DR3.

The display device 10 may further include a display driving circuit 200 located in the sub-region SBA of the display panel 100, a display circuit board 300 bonded to one side of the sub-region SBA, a touch driving circuit 400 mounted on the display circuit board 300, and a cable 600 extending from one side of the display circuit board 300.

One end of the display circuit board 300 may be attached to pads located at the lower edge of the sub-region SBA of the display device 10 by using an anisotropic conductive film.

The display circuit board 300 may be a flexible printed circuit board (FPCB) which is bendable, a rigid printed circuit board (PCB) which maintains a flat shape, or a composite printed circuit board having both characteristics of the rigid printed circuit board and the flexible printed circuit board.

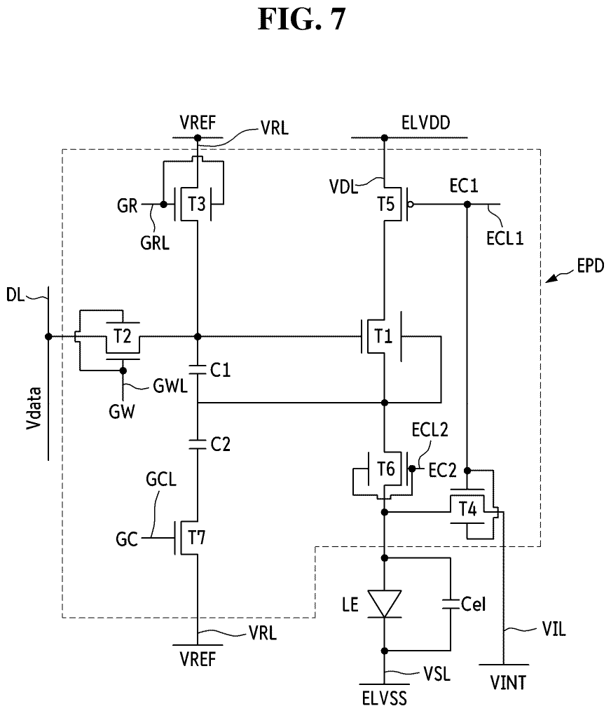

Based on control signals, power and voltages supplied from the display circuit board 300, the display driving circuit 200 may transmit a data signal Vdata (see FIG. 7) to each of light emitting pixel drivers EPD (see FIG. 7) in the display area DA through data lines DL (see FIG. 7).

The display driving circuit 200 may be an integrated circuit (IC) and may be mounted on the sub-region SBA of the display device 10 by using a chip on glass (COG) method, a chip on plastic (COP) method, or an ultrasonic method. However, this is only an example, and the present disclosure is not limited thereto. For example, the display driving circuit 200 may be mounted on the display circuit board 300.

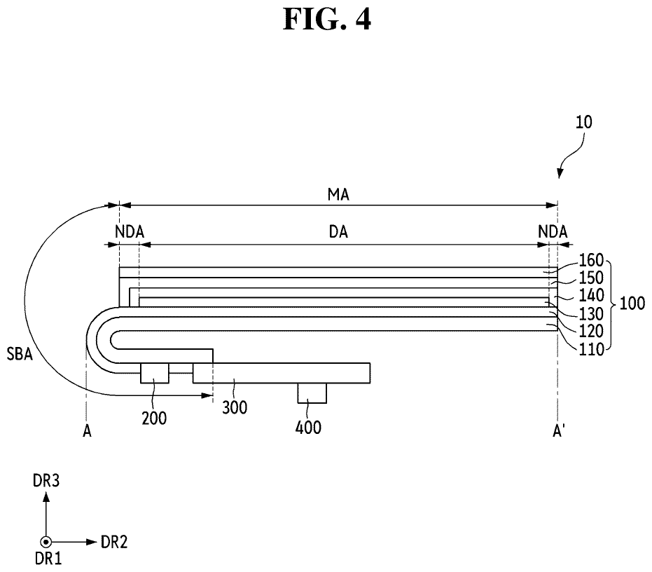

According to an embodiment, the touch driving circuit 400 may be located in the sub-region SBA of the display device 10. In another example, as shown in FIG. 2, the touch driving circuit 400 may be mounted on the display circuit board 300. The touch driving circuit 400 may be electrically connected to a touch sensor layer 150 (see FIG. 4) of the display device 10.

The bracket 13 may be located under the display device 10. The bracket 13 may include plastic or metal. The bracket 13 may include a first camera hole CMH1 into which a camera device 16 is inserted, a battery hole BH into which a battery 18 is located, and a cable hole CAH through which the cable 600 connected to the display circuit board 300 passes.

The main circuit board 14 and the battery 18 may be located under the bracket 13.

The main circuit board 14 may be a printed circuit board or a flexible printed circuit board. The main circuit board 14 may include a main processor 15, the camera device 16, and a main connector 17. The main processor 15 may be formed as an integrated circuit.

The camera device 16 may be located on both the top surface and the bottom surface of the main circuit board 14, the main processor 15 may be located on the top surface of the main circuit board 14, and the main connector 17 may be located on the bottom surface of the main circuit board 14.

The main processor 15 may control the functions of the electronic device 1. For example, the main processor 15 may output digital video data to the display driving circuit 200 through the display circuit board 300 such that the display device 10 displays an image. In addition, the main processor 15 may receive touch data including user's touch coordinates from the touch driving circuit 400, determine if the user has touched or approached the electronic device 1, and perform an operation corresponding to the user's touch input or approach input. For example, the main processor 15 may perform an operation or execute an application indicated by an icon touched by the user.

The main processor 15 may be an application processor including an integrated circuit, a central processing unit, or a system chip.

The camera device 16 may process an image frame of a still image or video obtained by an image sensor in the camera device 16 and output the processed image frame to the main processor 15.

The cable 600 having passed through the cable hole CAH of the bracket 13 may be connected to the main connector 17. Thus, the main circuit board 14 may be electrically connected to the display circuit board 300.

The battery 18 may be located so as not to overlap the main circuit board 14 in the third direction DR3. The battery 18 may overlap the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 18. The lower cover 12 may be fixed by being fastened to the bracket 13. The lower cover 12 may form a bottom surface of the electronic device 1. The lower cover 12 may include plastic, metal, or both plastic and metal.

The lower cover 12 may include a second camera hole CMH2 through which the bottom surface of the camera device 16 is exposed. The position of the camera device 16 and the positions of the first camera hole CMH1 and the second camera hole CMH2 corresponding to the camera device 16 are not limited to those illustrated in FIG. 2.

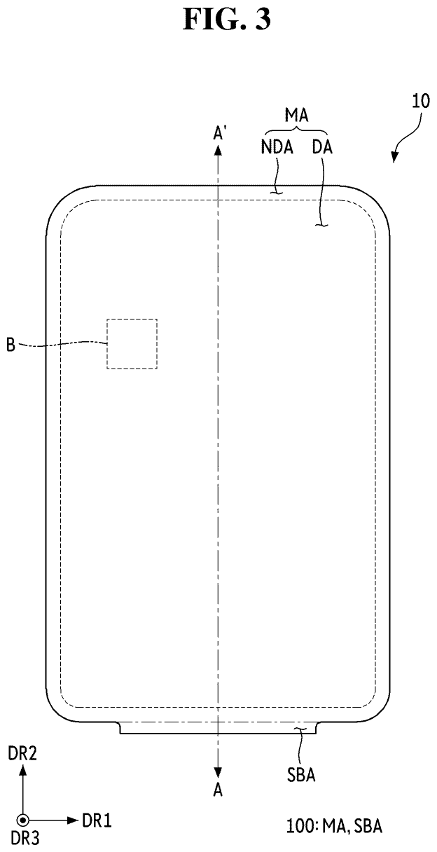

FIG. 3 is a plan view illustrating the display device of FIG. 2. FIG. 4 is a cross-sectional view taken along a line A-A′ of FIG. 3.

Referring to FIGS. 3 and 4, the display device 10 according to embodiments, which is a device for displaying a moving image or a still image, may be used as a display screen of various electronic devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as an organic light emitting display device including an organic light emitting diode, a quantum dot light emitting display device including a quantum dot light emitting layer, an inorganic light emitting display device including an inorganic semiconductor, and a micro light emitting display device including a micro or nano light emitting diode (LED). In the following description, it is assumed that the display device 10 according to an embodiment is an organic light emitting display device. However, the present disclosure is not limited thereto.

The display device 10 may have a flat top surface, but is not limited thereto. For example, the display device 10 may include a curved portion disposed at left and right ends and having a constant curvature or a varying curvature. In addition, the display device 10 may be flexible so that it can be curved, bent, folded, or rolled.

The display area DA may, in a plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a predetermined curvature or may be right-angled. However, the planar shape of the display area DA is not limited to the rectangular shape, and may be formed in a polygonal shape, a circular shape or an elliptical shape.

The display device 10 may include the display panel 100. The display panel 100 includes the main region MA and the sub-region SBA located on one side of the main region MA.

The main region MA may include the display area DA and the non-display area NDA. The display area DA may occupy most of the main region MA. The display area DA may be located at the center of the main region MA. The non-display area NDA may be located outside the display area DA. The non-display area NDA may be an edge area of the main region MA.

The sub-region SBA may protrude from at least a part of one side of the main region MA in the second direction DR2. Since a part of the sub-region SBA is bendable, another part of the sub-region SBA may be located on the rear surface of the display device 10.

According to an embodiment, the display device 10 may include the substrate 110, the circuit layer 120 located on the substrate 110, the element layer 130 located on the circuit layer 120, an encapsulation layer 140 located on the element layer 130, and a touch sensor layer 150 located on the encapsulation layer 140. The display device 10 may further include a polarization layer 160 located on the touch sensor layer 150, in order to reduce reflection of external light.

The substrate 110 may include an insulating material such as polymer resin. For example, the substrate 110 may include polyimide. The substrate 110 may be a flexible substrate which can be bent, folded or rolled. However, the present disclosure is not limited thereto. For example, the substrate 110 may include an insulating material such as glass or the like.

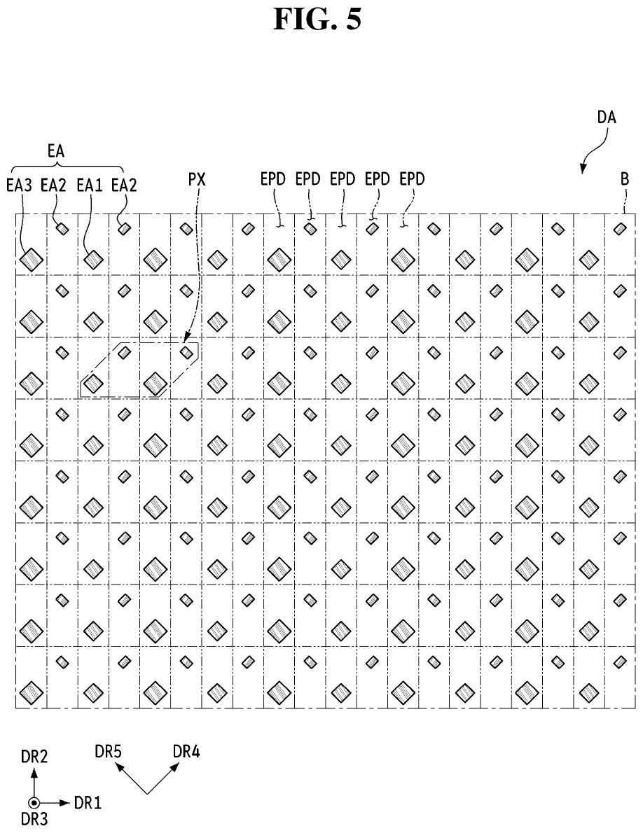

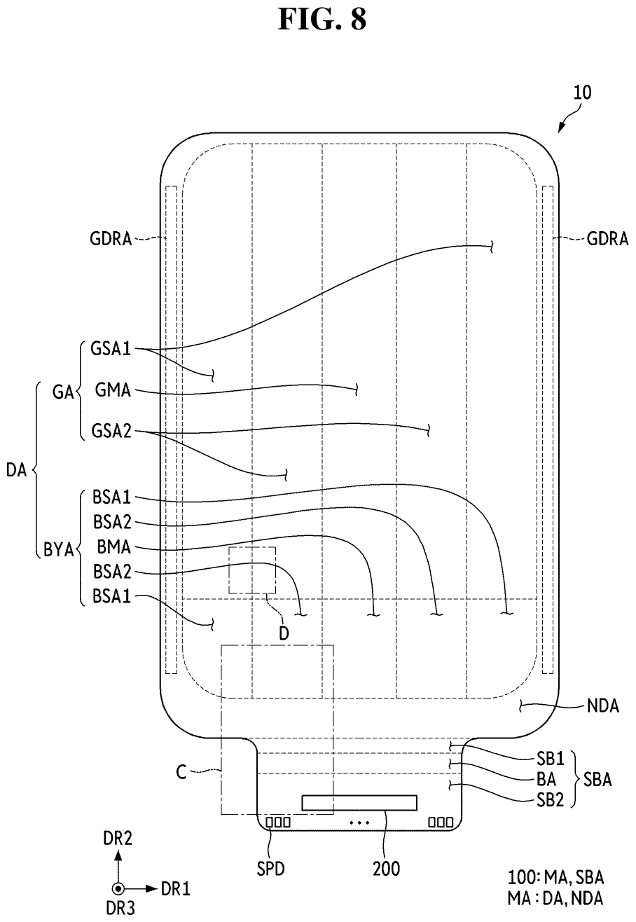

The circuit layer 120 may include the light emitting pixel drivers EPD (see FIG. 5) electrically connected to light emitting elements LE (see FIG. 8), and at least one constant voltage line that transmits at least one constant voltage to the light emitting pixel drivers EPD (see FIG. 5).

At least one constant voltage line may include a first power line VDL (see FIG. 7) that transmits a first power ELVDD (see FIG. 7), an initialization voltage line VIL (see FIG. 7) that transmits an initialization voltage VINT (see FIG. 7), and a reference voltage line VRL (see FIG. 7) that transmits a reference voltage VREF (see FIG. 7).

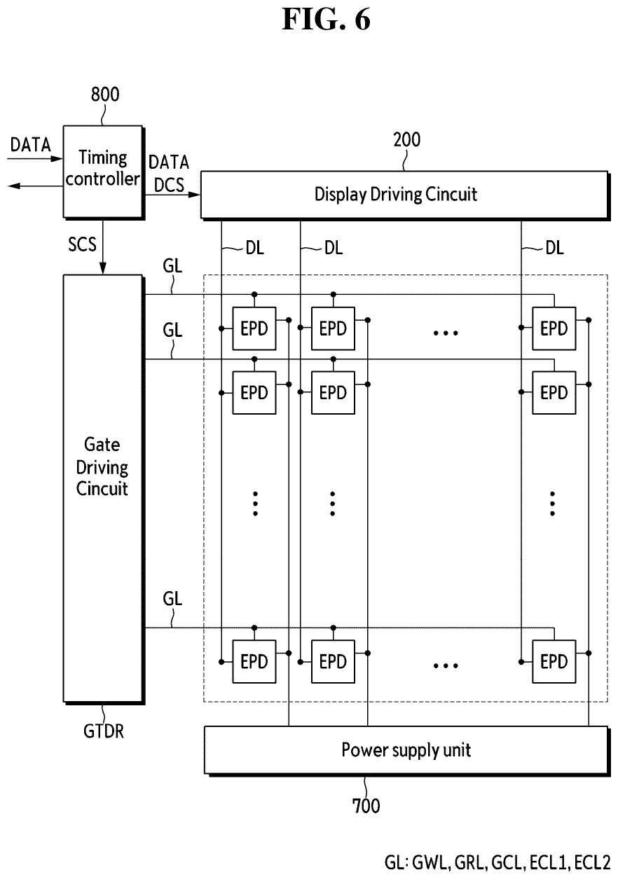

The circuit layer 120 may further include the data lines DL (see FIG. 6) that transmit the data signals Vdata (see FIG. 7) to the light emitting pixel drivers EPD (see FIG. 5).

The element layer 130 may include the light emitting elements LE (see FIG. 7) respectively located in the emission areas EA (see FIG. 5).

The encapsulation layer 140 may cover the element layer 130. The encapsulation layer 140 may include a structure in which two or more inorganic layers and at least one organic layer are alternately stacked.

The touch sensor layer 150 may be located on the encapsulation layer 140 and may correspond to the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, and prevents the deterioration of visibility of an image due to external light reflection.

As a part of the sub-region SBA is bendable, the display driving circuit 200 mounted on the sub-region SBA, the display circuit board 300 connected to one side of the sub-region SBA, and the touch driving circuit 400 mounted on the display circuit board 300 may be located below the substrate 110.

The display driving circuit 200 may be electrically connected to the data lines DL (see FIG. 6) of the circuit layer 120. The display driving circuit 200 may transmit the data signals Vdata (see FIG. 7) to the light emitting pixel drivers EPD (see FIG. 5) through the data lines DL (see FIG. 6) in response to control signals and power voltages supplied from the display circuit board 300.

The display driving circuit 200 may be provided as an integrated circuit (IC) and mounted on the sub-region SBA of the display device 10 by using a chip on glass (COG) method, a chip on plastic (COP) method, or an ultrasonic method. However, this is only an example, and the present disclosure is not limited thereto. For example, the display driving circuit 200 may be mounted on the display circuit board 300.

One end of the display circuit board 300 may be attached onto pads located on one edge of the sub-region SBA of the display device 10 by using an anisotropic conductive film. The display circuit board 300 may be a flexible printed circuit board (FPCB) which is bendable, a rigid printed circuit board (PCB) which maintains a flat shape, or a composite printed circuit board having both characteristics of the rigid printed circuit board and the flexible printed circuit board. The display circuit board 300 may be connected to the pads located on one side of the sub-region SBA.

The touch driving circuit 400 may be mounted on the display circuit board 300. The touch driving circuit 400 may be electrically connected to the touch sensor layer 150 of the display device 10.

The touch driving circuit 400 may apply a touch driving signal to driving lines of the touch sensor layer 150, and receive a touch sensing signal from sensing lines. Further, the touch driving circuit 400 may detect the change in charge of the capacitances based on the received touch sensing signal, thereby determining whether a user has touched or approached the electronic device.

The user's touch may refer to the direct contact of an object, such as a pen or a user's finger, with the top surface of the cover window located on the touch sensor layer. The user's approach may refer to the hovering of the object, such as the pen or the user's finger, over the top surface of the cover window.

The touch driving circuit 400 may output touch data including the user's touch coordinates to the main processor 15 (see FIG. 2).

FIG. 5 is an enlarged view illustrating part B of FIG. 3.

Referring to FIG. 5, the display area DA may include the emission areas EA from which light is emitted, and a non-emission area that is disposed between the emission areas EA and from which light is not emitted.

Each of the emission areas EA may be a unit area that emits light in a wavelength band corresponding to one color among two or more different colors with a luminance corresponding to an image signal.

Each of the emission areas EA may have a quadrilateral shape. However, this is only an example, and the planar shape of the emission areas EA according to an embodiment is not limited to that illustrated in FIG. 5. That is, the emission areas EA may have a planar shape of a polygon such as a rectangle, a square, a hexagon, and an octagon other than a rhombus, a circle, or an ellipse.

The emission areas EA may include first emission areas EA1 that emit light in a first wavelength band, second emission areas EA2 that emit light in a second wavelength band lower than the first wavelength band, and third emission areas EA3 that emit light in a third wavelength band lower than the second wavelength band.

For example, the first wavelength band may be from about 600 nm to about 750 nm and may correspond to a red color. The second wavelength band may be from about 480 nm to about 560 nm and may correspond to a green color. The third wavelength band may be from about 370 nm to about 460 nm and may correspond to a blue color. However, this is only an example, and the first wavelength band, the second wavelength band, and the third wavelength band according to an embodiment are not limited thereto.

Since the emission areas EA include the first emission area EA1, the second emission area EA2, and the third emission area EA3, each of unit pixels PX may include one or more first emission areas EA1, one or more second emission areas EA2, and one or more third emission areas EA3, which are adjacent to each other among the emission areas EA.

Each of the unit pixels PX may be a unit for displaying various colors including white. That is, lights of various colors displayed by the unit pixels PX may be implemented as a mixture of lights emitted from two or more emission areas EA included in each unit pixel PX.

The third emission area EA3 may have a width greater than that of the first emission area EA1, and the first emission area EA1 may have a width greater than that of the second emission area EA2. However, this is merely an example, and the width of each of the emission areas EA is not limited to those illustrated in FIG. 5.

The first emission areas EA1 and the third emission areas EA3 may be alternately arranged in the second direction DR2.

The second emission areas EA2 may be arranged repeatedly in the second direction DR2.

Each of the second emission areas EA2 may be adjacent to the first emission area EA1 or the third emission area EA3 in fourth and fifth directions DR4 and DR5 intersecting the first direction DR1 and the second direction DR2.

For example, each of the unit pixels PX may include one first emission area EA1 and one third emission area EA3 adjacent to each other in the first direction DR1, and two second emission areas EA2 adjacent to the first emission area EA1 and the third emission area EA3 in the fourth and fifth directions DR4 and DR5. However, this is only an example, and the arrangement pattern of the emission areas EA and the configuration of the unit pixel PX according to an embodiment are not limited to the above description.

According to an embodiment, the circuit layer 120 (see FIG. 4) may include the light emitting pixel drivers EPD arranged in the first direction DR1 and the second direction DR2 in the display area DA.

The light emitting pixel drivers EPD may be electrically connected to the light emitting elements LE (see FIG. 7) of the element layer 130 (see FIG. 4), respectively. The light emitting elements LE (see FIG. 7) may be located in the emission areas EA, respectively.

FIG. 6 is a block diagram illustrating the display device of FIG. 2.

Referring to FIG. 6, the circuit layer 120 of the display device 10 according to an embodiment may include the light emitting pixel drivers EPD electrically connected to the light emitting elements LE (see FIG. 7) located in the emission areas EA of the display area DA, and one or more gate lines GL that transmit one or more gate signals to the light emitting pixel drivers EPD.

The circuit layer 120 may further include the data lines DL that transmit the data signals Vdata (see FIG. 7) to the light emitting pixel drivers EPD.

According to an embodiment, the display device 10 may further include the display driving circuit 200 that outputs the data signals Vdata (see FIG. 8) to the light emitting pixel drivers EPD through the data lines DL in order to control the luminance of each of the light emitting elements LE (see FIG. 7).

According to an embodiment, the display device 10 may further include a gate driver GTDR that outputs the gate signals to the gate lines GL, a power supply unit 700 that supplies power and voltages to the light emitting pixel drivers EPD, and a timing controller 800 that controls the operation of each of the display driving circuit 200, the gate driver GTDR and the power supply unit 700.

The timing controller 800 receives an image signal supplied from the outside of the display device 10. The timing controller 800 may output image data DATA and a data control signal DCS to the display driving circuit 200. The timing controller 800 may generate a scan control signal SCS for controlling the operation of the gate driver GTDR.

The display driving circuit 200 may convert the image data DATA into analog data voltages and output the data signals Vdata to the data lines DL.

The gate driver GTDR may generate gate signals in response to the scan control signal SCS and sequentially output the gate signals to gate lines GL.

The gate lines GL may include a scan write line GWL that transmits a scan write signal GW (see FIG. 7), a reset control line GRL that transmits a reset control signal GR (see FIG. 7), a gate control line GCL that transmits a gate control signal GC (see FIG. 7), a first emission control line ECL1 that transmits a first emission control signal EC1 (see FIG. 7), and a second emission control line ECL2 that transmits a second emission control signal EC2 (see FIG. 7). The scan write signal GW (see FIG. 7), the reset control signal GR (see FIG. 7), the gate control signal GC (see FIG. 7), the first emission control signal EC1 (see FIG. 7), and the second emission control signal EC2 (see FIG. 7) may be included in the gate signal. The gate signals may have pulses that vary between a first gate level voltage and a second gate level voltage.

The power supply unit 700 may supply various power and voltages necessary for driving the light emitting pixel drivers EPD. For example, the power supply unit 700 may supply the first power ELVDD (see FIG. 7) and the second power ELVSS (see FIG. 7) for generating a driving signal transmitted to the light emitting elements LE (see FIG. 7), the reference voltage VREF (see FIG. 7) for initializing the light emitting pixel drivers EPD, and the initialization voltage VINT (see FIG. 7) for initializing the light emitting elements LE (see FIG. 7).

FIG. 7 is an equivalent circuit diagram illustrating the light emitting pixel driver according to an embodiment.

Referring to FIG. 7, the light emitting pixel drivers EPD of the circuit layer 120 (see FIG. 4) may be electrically connected to the light emitting elements LE of the element layer 130 (see FIG. 4), respectively.

The light emitting pixel drivers EPD may be electrically connected to the first power line VDL that transmits the first power ELVDD, and the light emitting elements LE may be electrically connected to the second power line VSL that transmits the second power ELVSS that is different from the first power ELVDD. The second power ELVSS may have a voltage level lower than that of the first power ELVDD.

That is, the anode electrode of the light emitting element LE may be electrically connected to the light emitting pixel driver EPD, and the cathode electrode of the light emitting element LE may be electrically connected to the second power line VSL.

The light emitting pixel drivers EPD may be electrically connected to the scan write line GWL that transmits the scan write signal GW, the reset control line GRL that transmits the reset control signal GR, the gate control line GCL that transmits the gate control signal GC, the first emission control line ECL1 that transmits the first emission control signal EC1, and the second emission control line ECL2 that transmits the second emission control signal EC2.

Each of the light emitting pixel drivers EPD may include a first transistor T1 generating a driving current transmitted to the light emitting element LE, two or more transistors T2 to T7 electrically connected to the first transistor T1, and one or more capacitors C1 and C2.

A second transistor T2 may be electrically connected between the gate electrode of the first transistor T1 and the data line DL. The second transistor T2 may be turned on in response to the scan write signal GW of the scan write line GWL. When the second transistor T2 is turned on, the data signal Vdata of the data line DL may be transmitted to the gate electrode of the first transistor T1.

When the voltage difference between the gate electrode of the first transistor T1 and the second electrode of the first transistor T1 is equal to or greater than the threshold voltage of the first transistor T1 due to the data signal Vdata applied to the gate electrode of the first transistor T1, the first transistor T1 may be turned on. Accordingly, a drain-source current of the first transistor T1 may be generated to have a magnitude corresponding to the data signal Vdata. The drain-source current of the first transistor T1 may be referred to as the driving current of the first transistor T1.

A third transistor T3 may be electrically connected between the gate electrode of the first transistor T1 and the reference voltage line VRL. The third transistor T3 may be turned on in response to the reset control signal GR of the reset control line GRL. When the third transistor T3 is turned on, the potential of the gate electrode of the first transistor T1 may be initialized to the reference voltage VREF of the reference voltage line VRL.

The fourth transistor T4 may be electrically connected between the light emitting element LE and the initialization voltage line VIL. The fourth transistor T4 may be turned on in response to the first emission control signal EC1 of the first emission control line ECL1. When the fourth transistor T4 is turned on, the potential of the anode electrode of the light emitting element LE may be initialized to the initialization voltage VINT of the initialization voltage line VIL.

The fifth transistor T5 may be electrically connected between the first electrode of the first transistor T1 and the first power line VDL. The fifth transistor T5 may be turned on in response to the first emission control signal EC1 of the first emission control line ECL1.

The sixth transistor T6 may be electrically connected between the second electrode of the first transistor T1 and the light emitting element LE. The sixth transistor T6 may be turned on in response to the second emission control signal EC2 of the second emission control line ECL2.

When the fifth transistor T5 and the sixth transistor T6 are turned on, the first transistor T1 and the light emitting element LE are connected in series between the first power source ELVDD and the second power source ELVSS so that the drain-source current of the first transistor T1 which has a magnitude corresponding to the data signal Vdata may be transmitted to the light emitting element LE. Accordingly, the light emitting element LE may emit light having a luminance corresponding to the data signal Vdata.

The first capacitor C1 may be electrically connected between the gate electrode of the first transistor T1 and the second electrode of the first transistor T1. Accordingly, the first capacitor C1 may be charged with the data signal Vdata applied to the gate electrode of the first transistor T1, and the turning-on state of the first transistor T1 may be maintained for a selected period due to the voltage charged in the first capacitor C1.

A second capacitor C2 may be electrically connected between the second electrode of the first transistor T1 and the second electrode of the seventh transistor T7.

The seventh transistor T7 may be electrically connected between the second capacitor C2 and the reference voltage line VRL. The seventh transistor T7 may be turned on in response to the gate control signal GC of the gate control line GCL. When the seventh transistor T7 is turned on, the potential of the gate electrode of the first transistor T1 may be initialized to the reference voltage VREF of the reference voltage line VRL.

The first transistor T1 may include the gate electrode facing one surface of a channel portion and a gate additional electrode facing the other surface of the channel portion. The channel portion of the first transistor T1 may be interposed between the gate electrode and the gate additional electrode. That is, the first transistor T1 may have a double-gate structure.

The gate electrode of the first transistor T1 may be electrically connected to the second transistor T2. The gate additional electrode of the first transistor T1 may be electrically connected to the second electrode of the first transistor T1.

Accordingly, when the data signal Vdata is applied to the gate electrode of the first transistor T1 such that the first transistor T1 is turned-on, while a portion of the channel portion of the first transistor T1 facing the gate electrode is activated, the other portion of the channel portion of the first transistor T1 facing the gate additional electrode may remain inactive.

Therefore, since the electron mobility in the channel portion of the first transistor T1 decreases, the slope of a current curve representing a relationship between the drain-source current and the voltage of the gate electrode of the first transistor T1 may become gentle. Accordingly, a driving voltage range of the first transistor T1 may be widened, which may facilitate luminance control.

According to an embodiment, at least some of the second to seventh transistors T2 to T7 may include a gate electrode facing one surface of the channel portion, and a gate additional electrode facing the other surface of the channel portion. The respective channel portions of at least some of the second to seventh transistors T2 to T7 may be interposed between the gate electrode and the gate additional electrode. That is, at least some of the second to seventh transistors T2 to T7 may have a double-gate structure.

For example, as illustrated in FIG. 7, each of the second transistor T2, the third transistor T3, the fourth transistor T4, and the sixth transistor T6 may include a gate electrode and a gate additional electrode. Each of the gate electrodes of the second transistor T2, the third transistor T3, the fourth transistor T4, and the sixth transistor T6 may be electrically connected to each of the gate additional electrodes of the second transistor T2, the third transistor T3, the fourth transistor T3, and the sixth transistor T6.

Since each of the second transistor T2, the third transistor T3, the fourth transistor T4, and the sixth transistor T6 has a double-gate structure, the capability of the gate electrode to control the channel portion may be improved, the leakage current may be reduced, and the operating speed may be improved.

According to an embodiment, the first transistor T1 may be an N-type MOSFET. At least some of the second to sixth transistors T2 to T6 may be P-type MOSFETs. For example, the fifth transistor T5 may be a P-type MOSFET, and the second transistor T2, the third transistor T3, the fourth transistor T4, the sixth transistor T6, and the seventh transistor T7 may be N-type MOSFETs.

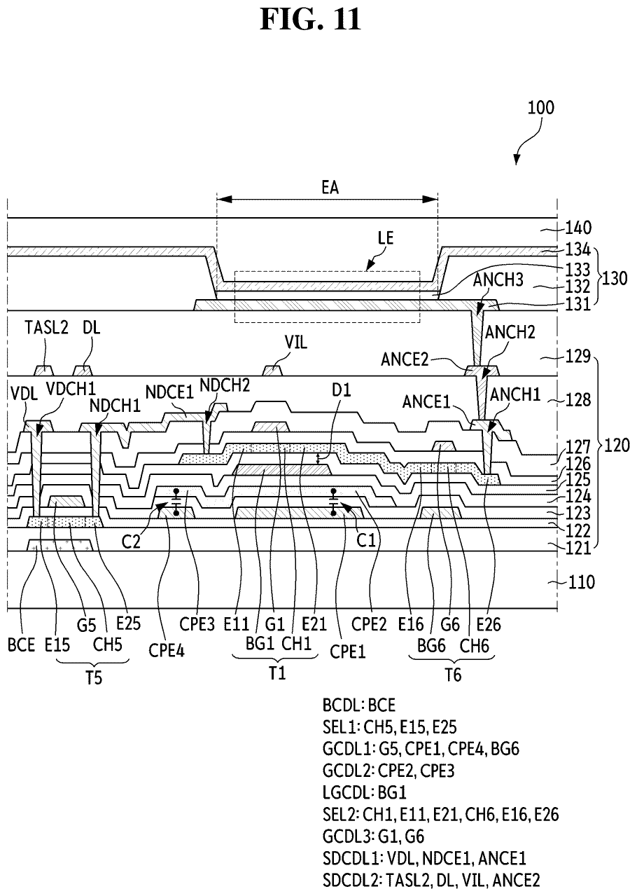

Accordingly, according to an embodiment, the circuit layer 120 (see FIG. 4) may include a first semiconductor layer SEL1 (see FIG. 11) for preparing a P-type MOSFET, and a second semiconductor layer SEL2 (see FIG. 11) for preparing an N-type MOSFET.

Additionally, according to an embodiment, in order to improve the driving characteristics of the first transistor T1, at least some of the first to seventh transistors T1 to T7 may be oxide transistors including oxide semiconductors. For example, each active layer of at least some of the first to seventh transistors T1 to T7 may include an oxide semiconductor. Among the first to seventh transistors T1 to T7, the remaining transistors, excluding the oxide transistors, may include other semiconductor materials (e.g., amorphous silicon or polysilicon) other than oxide semiconductors.

For example, the fifth transistor T5 may be a transistor including a silicon semiconductor, and the first to fourth transistors T1 to T4 and the sixth and seventh transistors T6 and T7 may be transistors including oxide semiconductors.

The oxide semiconductor may have high carrier mobility and a low leakage current, so that a considerable voltage drop may not occur even if the driving time of the oxide transistor increases. For example, the pixel PX including an oxide transistor may be driven at a low frequency because the change in the luminance and/or the color of an image due to a voltage drop is not significant even when it is driven at a low frequency. When at least some of the first to seventh transistors T1 to T7 include oxide transistors, the leakage current of the pixel PX may be reduced or prevented and the power consumption may be reduced.

FIG. 8 is a plan view illustrating a display panel and a display driving circuit according to one embodiment.

Referring to FIGS. 7 and 8, the display panel 100 may include the main region MA corresponding to the display surface and the sub-region SBA protruding from a part of one side of the main region MA.

The main region MA may include the display area DA occupying most of the center of the main region MA, and the non-display area NDA surrounding at least a portion of the display area DA.

The display area DA may include a bypass area BYA located on one side adjacent to the sub-region SBA, and a general area GA located in the remaining area excluding the bypass area BYA.

The bypass area BYA may include a bypass middle area BMA located at the center of the bypass area BYA in the first direction DR1, a first bypass side area BSA1 located in parallel with the bypass middle area BMA in the first direction DR1 and in contact with the non-display area NDA, and a second bypass side area BSA2 located between the bypass middle area BMA and the first bypass side area BSA1.

For example, the first bypass side areas BSA1 may be located in opposite sides with respect to the bypass middle area BMA in the first direction DR1, respectively. The second bypass side areas BSA2 may also be located in opposite sides with respect to the bypass middle area BMA in the first direction DR1, respectively, and may be disposed between each of the first bypass side areas BSA1 and the bypass middle area BMA. That is, the first bypass side area BSA1 and the second bypass side area BSA2 may be located between the non-display area NDA and the bypass middle area BMA in the first direction DR1.

The first bypass side area BSA1 may be located adjacent to the corner of the display panel 100 having a curvature as compared to the bypass middle area BMA and the second bypass side area BSA2.

The general area GA may include a general middle area GMA disposed adjacent to the bypass middle area BMA of the bypass area BYA in the second direction DR2, a first general side area GSA1 disposed adjacent to the first bypass side area BSA1 of the bypass area BYA in the second direction DR2, and a second general side area GSA2 disposed adjacent to the second bypass side area BSA2 of the bypass area BYA in the second direction DR2.

The non-display area NDA may include a gate driving circuit area GDRA where a gate driving circuit is located.

The gate driving circuit area GDRA may face one side of the display area DA extending in the second direction DR2. However, this is merely an example, and the gate driving circuit area GDRA may be located in the display area DA, rather than in the non-display area NDA.

A gate driving circuit (e.g., the gate driver GTDR (see FIG. 6)) in the gate driving circuit area GDRA may sequentially transmit gate signals to gate lines. Here, the gate lines may include the scan write line GWL that transmits the scan write signal GW, the reset control line GRL that transmits the reset control signal GR, the gate control line GCL that transmits the gate control signal GC, the first emission control line ECL1 that transmits the first emission control signal EC1, and the second emission control line ECL2 that transmits the second emission control signal EC2.

The sub-region SBA may include the bending area BA that is transformed into a bent shape, the first sub-region SB1 located between one side of the bending area BA and the main region MA, and the second sub-region SB2 disposed adjacent to the other side of the bending area BA.

When the bending area BA is bent, the second sub-region SB2 may be arranged below the main region MA and may overlap the main region MA.

The display driving circuit 200 may be located in the second sub-region SB2.

The signal pads SPD bonded to the circuit board 300 (see FIG. 2) may be arranged at one edge of the second sub-region SB2.

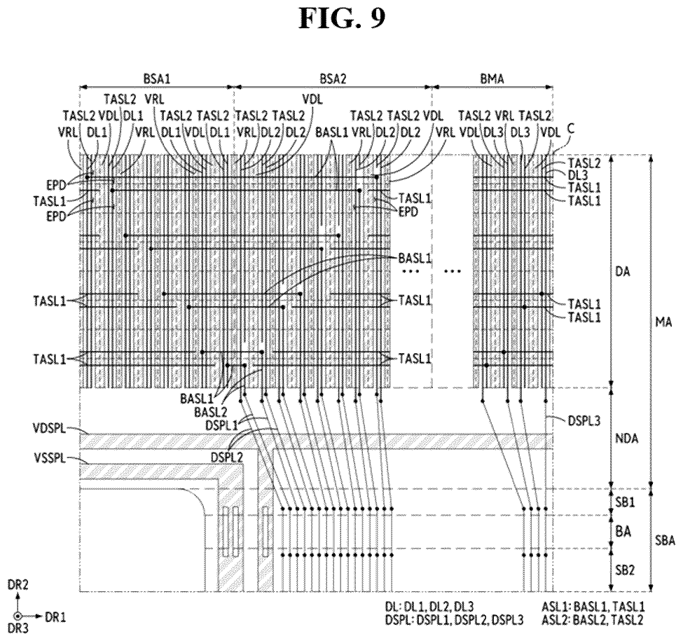

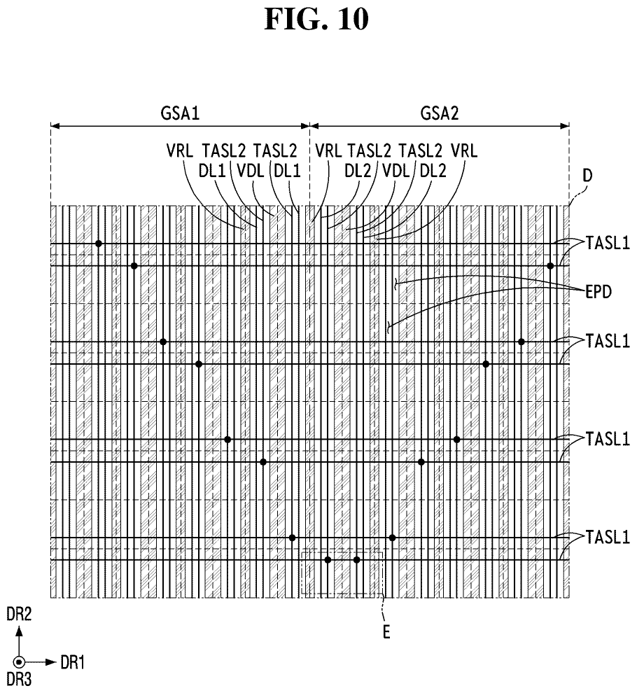

FIG. 9 is a plan view illustrating a circuit layer of part C of FIG. 8. FIG. 10 is a plan view illustrating a circuit layer of part D of FIG. 8.

Referring to FIGS. 8 to 10, the circuit layer 120 (see FIG. 4) of the display device 10 may include the light emitting pixel drivers EPD that are electrically connected to the light emitting elements LE (see FIG. 7) of the element layer 130 (see FIG. 4), respectively and arranged parallel to each other in the first direction DR1 and the second direction DR2, the data lines DL that extend in the second direction DR2 and transmit the data signals Vdata (see FIG. 7) to the light emitting pixel drivers EPD, first auxiliary lines ASL1 that extend in the first direction DR1, and second auxiliary lines ASL2 that extend in the second direction DR2 and are adjacent to the data lines DL.

The first auxiliary lines ASL1 may include a first bypass auxiliary line BASL1 electrically connected to a first data line DL1 among the data lines DL, which is adjacent to the non-display area NDA in the first direction DR1, and first transmission auxiliary lines TASL1 other than the first bypass auxiliary line BASL1.

The second auxiliary lines ASL2 may include a second bypass auxiliary line BASL2 electrically connected to the first bypass auxiliary lines BASL1, and second transmission auxiliary lines TASL2 other than the second bypass auxiliary lines BASL2.

The second bypass auxiliary line BASL2 may neighbor the second data line DL2 among the data lines DL, which is spaced further apart from the non-display area NDA in the first direction DR1 than the first data line DL1.

The first data line DL1 may be located in the first bypass side area BSA1.

The second data line DL2 and the second bypass auxiliary line BASL2 may be located in the second bypass side area BSA2.

The first bypass auxiliary line BASL1 may be located in both a portion of the first bypass side area BSA1 and a portion of the second bypass side area BSA2.

As illustrated in FIG. 9, the circuit layer 120 (see FIG. 4) may further include data supply lines DSPL located in the non-display area NDA and electrically connected to the display driving circuit 200 and the data lines DL.

The data supply lines DSPL may extend either to the bypass middle area BMA or to the second bypass side area BSA2.

The data supply lines DSPL may include a first data supply line DSPL1 that transmits the data signal of the first data line DL1, and a second data supply line DSPL2 that transmits the data signal of the second data line DL2.

The first data supply line DSPL1 may extend to the second bypass auxiliary line BASL2 of the second bypass side area BSA2, and may be electrically connected to the first data line DL1 through the second bypass auxiliary line BASL2 and the first bypass auxiliary line BASL1.

The second data supply line DSPL2 may extend to the second bypass side area BSA2, and may be electrically connected to the second data line DL2 directly.

According to an embodiment, since the first data supply line DSPL1 does not extend to the first data line DL1 in the first bypass side area BSA1 directly but is connected to the first data line DL1 indirectly through the second bypass auxiliary line BASL2 in the second bypass side area BSA2, the extension length of the first data supply line DSPL1 may be shortened. As a result, the width of the area required for the arrangement of the data supply lines DSPL may be reduced, so that the width of the non-display area NDA may be reduced.

In addition, since the data supply lines DSPL are not located in a portion of the non-display area NDA adjacent to the bent edge of the display panel 100, the width of the non-display area NDA may be further reduced.

The data lines DL may further include a third data line DL3 located in the bypass middle area BMA. In addition, the data supply lines DSPL may further include a third data supply line DSPL3 that transmits the data signal of the third data line DL3.

The third data supply line DSPL3 may extend to the bypass middle area BMA, and may be electrically connected directly to the third data line DL3.

The first bypass auxiliary line BASL1 may be elongated from a portion the first data line DL1 to a portion of the second bypass auxiliary line BASL2.

The second bypass auxiliary line BASL2 may be located between the first data supply line DSPL1 and the first bypass auxiliary line BASL1.

Since the first bypass auxiliary line BASL1 and the second bypass auxiliary line BASL2 are located in a portion of the bypass area BYA, and the ends of the first bypass auxiliary line BASL1 and the ends of the second bypass auxiliary line BASL2 are located in the display area DA, the visibility of the first bypass auxiliary line BASL1 and the second bypass auxiliary line BASL2 may be improved.

To prevent this, the first auxiliary lines ASL1 may further include not only the first bypass auxiliary line BASL1 but also first transmission auxiliary lines TASL1. Also, the second auxiliary lines ASL2 may further include not only the second bypass auxiliary line BASL2 but also the second transmission auxiliary lines TASL2.

Two of the first transmission auxiliary lines TASL1 among a plurality of first transmission auxiliary lines TASL1 may be disposed adjacent to corresponding two of the first bypass auxiliary line BASL1 in the display area DA, and each of two of the first transmission auxiliary lines TASL1 may extend from a portion spaced apart from one end of the corresponding first bypass auxiliary line BASL1 in the first direction DR1 to the non-display area NDA.

One of the second transmission auxiliary lines TASL2 among a plurality of second transmission auxiliary lines TASL2 may be disposed adjacent to a corresponding second bypass auxiliary line BASL in the display area DA, and may extend from a portion spaced apart from one end of the corresponding second bypass auxiliary line BASL2 in the second direction DR2 to the non-display area NDA in a direction away from the sub-region SBA.

Since the second bypass auxiliary lines BASL2 are located only in the second bypass side area BSA2, each of the first data line DL1 in the first bypass side area BSA1 and the third data line DL3 in the bypass middle area BMA may be entirely adjacent to the second transmission auxiliary lines TASL2.

According to an embodiment, each of the first transmission auxiliary lines TASL1 and the second transmission auxiliary lines TASL2 may be electrically connected to one of the first power line VDL (see FIG. 7) that transmits the first power ELVDD (see FIG. 7), the second power line VSL (see FIG. 7) that transmits the second power ELVSS (see FIG. 7), the initialization voltage line VIL (see FIG. 7) that transmits the initialization voltage VINT (see FIG. 7), and the reference voltage line VRL (see FIG. 7) that transmits the reference voltage VREF (see FIG. 7). Accordingly, the resistance of the path through which power or a constant voltage is transmitted may be reduced by the first transmission auxiliary lines TASL1 and the second transmission auxiliary lines TASL2.

According to an embodiment, the circuit layer 120 (see FIG. 4) may further include a first power supply line VDSPL and a second power supply line VSSPL that are located in the non-display area NDA and extend to the sub-region SBA.

The first power supply line VDSPL may transmit the first power ELVDD (see FIG. 7), and the second power supply line VSSPL may transmit the second power ELVSS (see FIG. 7).

The first power supply line VDSPL may be electrically connected to a first power pad for transmitting the first power ELVDD (see FIG. 7) among the signal pads SPD located in the second sub-region SB2.

The second power supply line VSSPL may be electrically connected to a second power pad for transmitting the second power ELVSS (see FIG. 7) among the signal pads SPD located in the second sub-region SB2.

For example, at least some of the first transmission auxiliary lines TASL1 may be electrically connected to the second power supply line VSSPL.

In addition, at least some of the second transmission auxiliary lines TASL2 may be electrically connected to at least some of the first transmission auxiliary lines TASL1 and the second power supply line VSSPL.

According to an embodiment, the circuit layer 120 (see FIG. 4) may further include the first power lines VDL transmitting the first power ELVDD (see FIG. 7) to the light emitting pixel drivers EPD.

The first power lines VDL may extend in the second direction DR2 and may be electrically connected to the first power supply line VDSPL.

The first power lines VDL may be located between two second auxiliary lines ASL2 adjacent to each other in the first direction DR1.

According to an embodiment, the circuit layer 120 (see FIG. 4) may further include the reference voltage lines VRL that transmit the reference voltage VREF (see FIG. 7) to the light emitting pixel drivers EPD.

The reference voltage lines VRL may extend in the second direction DR2.

The reference voltage lines VRL may be located between two data lines DL adjacent in the first direction DR1.

As shown in FIG. 10, the first transmission auxiliary lines TASL1 of the first auxiliary lines ASL1 and the second transmission auxiliary lines TASL2 of the second auxiliary lines ASL2 may be located in the general area GA.

Each of the first transmission auxiliary lines TASL1 may be electrically connected to at least some of the second transmission auxiliary lines TASL2.

As illustrated in FIGS. 9 and 10, according to an embodiment, two of the first transmission auxiliary lines TASL1 may be located adjacent to a boundary between two light emitting pixel drivers EPD adjacent in the second direction DR1.

The data lines DL may include the first data line DL1 in the first bypass side area BSA1 and the second data line DL2 in the second bypass side area BSA2.

The second auxiliary lines ASL2 may include the second bypass auxiliary line BASL2 that transmits the data signal to the first data line DL1, and the second transmission auxiliary lines TASL2.

The second bypass auxiliary line BASL2 may be adjacent to the second data line DL2 in the second bypass side area BSA2.

The first auxiliary lines ASL1 may be included in a first source-drain conductive layer SDCDL1.

The first auxiliary lines ASL1 may include the first bypass auxiliary line BASL1 that transmits the data signal to the first data line DL1, and the first transmission auxiliary lines TASL1.

FIG. 11 is a cross-sectional view illustrating the first transistor, the fifth transistor, the sixth transistor, the first capacitor, the second capacitor, and the light emitting element of FIG. 7.

Referring to FIG. 11 with reference to FIG. 7, the display panel 100 of the display device 10 according to an embodiment may include the substrate 110, the circuit layer 120 disposed on the substrate 110, the element layer 130 disposed on the circuit layer 120, and the encapsulation layer 140 disposed on the element layer 130.

The circuit layer 120 may include a lower conductive layer BCDL, a first buffer layer 121, a first semiconductor layer SEL1, a first gate insulating layer 122, a first gate conductive layer GCDL1, a first interlayer insulating layer 123, a second gate conductive layer GCDL2, a second interlayer insulating layer 124, a lower gate conductive layer LGCDL, a second buffer layer 125, a second semiconductor layer SEL2, a second gate insulating layer 126, a third gate conductive layer GCDL3, a third interlayer insulating layer 127, a first source-drain conductive layer SDCDL1, a first planarization layer 128, a second source-drain conductive layer SDCDL2, and a second planarization layer 129.

The lower conductive layer BCDL may include a lower electrode BCE.

The first semiconductor layer SEL1 may include a channel portion CH5, a first electrode E15, and a second electrode E25 of the fifth transistor T5.

The first gate conductive layer GCDL1 may include a gate electrode G5 of the fifth transistor T5, a first capacitor electrode CPE1, a fourth capacitor electrode CPE4, and a gate additional electrode BG6 of the sixth transistor T6.

The second gate conductive layer GCDL2 may include a second capacitor electrode CPE2 and a third capacitor electrode CPE3.

The lower gate conductive layer LGCDL may include a gate additional electrode BG1 of the first transistor T1.

The second semiconductor layer SEL2 may include a channel portion CH1, a first electrode E11, and a second electrode E21 of the first transistor T1, and a channel portion CH6, a first electrode E16, and a second electrode E26 of the sixth transistor T6.

The third gate conductive layer GCDL3 may include a gate electrode G1 of the first transistor T1 and a gate electrode G6 of the sixth transistor T6.

The first source-drain conductive layer SDCDL1 may include the first power line VDL, a first node connection electrode NDCE1, and a first anode connection electrode ANCE1.

The second source-drain conductive layer SDCDL2 may include the second transmission auxiliary line TASL2, the data line DL, the initialization voltage line VIL, and a second anode connection electrode ANCE2.

As illustrated in FIG. 7, each of the light emitting pixel drivers EPD may include the first transistor T1, the second transistor T2, the third transistor T3, the fourth transistor T4, the fifth transistor T5, the sixth transistor T6, the seventh transistor T7, the first capacitor C1, and the second capacitor C2.

Each of the first transistor T1, the second transistor T2, the third transistor T3, the fourth transistor T4, the fifth transistor T5, the sixth transistor T6, and the seventh transistor T7 may include a gate electrode, a channel portion overlapping the gate electrode, a first electrode connected to one side of the channel portion, and a second electrode connected to the other side of the channel portion.

According to an embodiment, the first, second, third, fourth, sixth, and seventh transistors T1, T2, T3, T4, T6, and T7 may be N-type MOSFETs, and the fifth transistor T5 may be a P-type MOSFET.

The first semiconductor layer SEL1 may include the channel portion CH5, the first electrode E15, and the second electrode E25 of the fifth transistor T5 prepared as a P-type MOSFET.

The first gate conductive layer GCDL1 may include the gate electrode G5 of the fifth transistor T5.

For example, the first semiconductor layer SEL1 may include a silicon semiconductor material such as polysilicon or amorphous silicon.

That is, the fifth transistor T5 may include the channel portion CH5, the first electrode E15 connected to one side of the channel portion CH5, the second electrode E25 connected to the other side of the channel portion CH5, and the gate electrode G5 overlapping the channel portion CH5.

The first electrode E15 of the fifth transistor T5 may be electrically connected to the first power line VDL. The first power line VDL may be included in the first source-drain conductive layer SDCDL1. The first power line VDL may be electrically connected to the first electrode E15 of the fifth transistor T5 through a first power contact hole VDCH1.

According to an embodiment, the lower electrode BCE may be located below the fifth transistor T5. The lower electrode BCE may prevent parasitic capacitance from occurring between the fifth transistor T5 and signal lines and thus improve the driving speed of the fifth transistor T5. Additionally, the lower electrode BCE may function as a shielding electrode to minimize electromagnetic interference coming from outside.

The second semiconductor layer SEL2 may include the channel portion CH1, the first electrode E11, and the second electrode E21 of the first transistor T1, and the channel portion CH6, the first electrode E16 and the second electrode E21 of the sixth transistor T6 that are prepared as N-type MOSFETs.

In addition, the third gate conductive layer GCDL3 may include the gate electrode G1 of the first transistor T1 and the gate electrode G6 of the sixth transistor T6.

The second semiconductor layer SEL2 may include an oxide semiconductor material.

The first transistor T1 may include the channel portion CH1, the first electrode E11 connected to one side of the channel portion CH1, the second electrode E21 connected to the other side of the channel portion CH1, and the gate electrode G1 overlapping the channel portion CH1.

According to an embodiment, the first transistor T1 may further include the gate additional electrode BG1 included in the lower gate conductive layer LGCDL. As illustrated in FIG. 7, the gate additional electrode BG1 of the first transistor T1 may be electrically connected to the second electrode E21 of the first transistor T1.

The sixth transistor T6 may include the channel portion CH6, the first electrode E16 connected to one side of the channel portion CH6, the second electrode E26 connected to the other side of the channel portion CH6, and the gate electrode G6 overlapping the channel portion CH6.

The first electrode E11 of the first transistor T1 may be electrically connected to the second electrode E25 of the fifth transistor T5 through the first node connection electrode NDCE1. The first node connection electrode NDCE1 may be included in the first source-drain conductive layer SDCDL1. The first node connection electrode NDCE1 may be electrically connected to the first electrode E11 of the first transistor T1 through a second node contact hole NDCH2. The first node connection electrode NDCE1 may be electrically connected to the second electrode E25 of the fifth transistor T5 through a first node contact hole NDCH1.

The second electrode E21 of the first transistor T1 may be integrated with the first electrode E16 of the sixth transistor T6.

According to an embodiment, the sixth transistor T6 may further include the gate additional electrode BG6 included in the first gate conductive layer GCDL1. As illustrated in FIG. 7, the gate additional electrode BG6 of the sixth transistor T6 may be electrically connected to the gate electrode G6 of the sixth transistor T6.

The second electrode E26 of the sixth transistor T6 may be electrically connected to the anode electrode 131 of the light emitting element LE through the first anode connection electrode ANCE1 and the second anode connection electrode ANCE2.

The first anode connection electrode ANCE1 may be included in the first source-drain conductive layer SDCDL1 and disposed on the third interlayer insulating layer 127. The first anode connection electrode ANCE1 may be electrically connected to the second electrode E26 of the six transistor T6 through a first anode contact hole ANCH1. The first anode contact hole ANCH1 may extend through the second gate insulating layer 126 and the third interlayer insulating layer 127.

The second anode connection electrode ANCE2 may be included in the second source-drain conductive layer SDCDL2 and disposed on the first planarization layer 128. The second anode connection electrode ANCE2 may be electrically connected to the first anode connection electrode ANCE1 through a second anode contact hole ANCH2 extending through the first planarization layer 128.

The first gate conductive layer GCDL1 may include the first capacitor electrode CPE1 and the fourth capacitor electrode CPE4.

The second gate conductive layer GCDL2 may include the second capacitor electrode CPE2 overlapping the first capacitor electrode CPE1, and the third capacitor electrode CPE3 overlapping the fourth capacitor electrode CPE4. The second capacitor electrode CPE2 and the third capacitor electrode CPE3 may be integrated with each other.

The first capacitor C1 may be formed in an area where the first capacitor electrode CPE1 and the second capacitor electrode CPE2 overlap each other. The second capacitor C2 may be formed in an area where the third capacitor electrode CPE3 and the fourth capacitor electrode CPE4 overlap each other.

Although not illustrated in the drawing, the first capacitor electrode CPE1 may be electrically connected to the gate electrode G1 of the first transistor T1, the second capacitor electrode CPE2 and the third capacitor electrode CPE3 may be electrically connected to the second electrode E21 of the first transistor T1, and the fourth capacitor electrode CPE4 may be electrically connected to the first electrode of the seventh transistor T7.

Since the third capacitor electrode CPE3 is electrically connected to the second electrode E21 of the first transistor T1, the first capacitor C1 may be formed in an area where the first capacitor electrode CPE1 and the third capacitor electrode CPE3 overlap each other.

The element layer 130 may be disposed on the circuit layer 120, and may include the light emitting elements LE, each of which is disposed in an area corresponding to the emission areas EA.

Each of the light emitting elements LE may include the anode electrode 131 and a cathode electrode 134 on the anode electrode 131, and a light emitting layer 133 disposed between the anode electrode 131 and the cathode electrode 134. The element layer 130 may include the anode electrodes 131 arranged to correspond to the emission area EA, a pixel defining layer 132 disposed in an area corresponding to the non-emission area and covering the edge of the anode electrode 131, the light emitting layers 133 disposed on the anode electrodes 131, and the cathode electrode 134 disposed on the light emitting layers 133 and the pixel defining layer 132.

Each of the light emitting elements LE may further include a first common layer disposed between the anode electrode 131 and the light emitting layer 133, and a second common layer disposed between the light emitting layer 133 and the cathode electrode 134.

The anode electrode 131 may be disposed in an area correspond to each of the emission areas EA, and may be electrically connected to a light emitting pixel driver EPD of the circuit layer 120. The anode electrode 131 may be referred to as a pixel electrode.

The anode electrode 131 may be disposed on the second planarization layer 129, and may be electrically connected to the second anode connection electrode ANCE2 through a third anode contact hole ANCH3 extending through the second planarization layer 129.

The light emitting layer 133 may include an organic light emitting material that converts electron-hole pairs into light.

The cathode electrode 134 may be disposed in the display area DA including the emission area EA. Since the second power ELVSS is commonly applied to the cathode electrode 134, it may be a part of the second power line VSL. The cathode electrode 134 may be referred to as a common electrode.

The encapsulation layer 140 may be disposed on the circuit layer 120 and cover the element layer 130. For example, the encapsulation layer 140 may include a first encapsulation layer disposed on the element layer 130 and including an inorganic insulating material, a second encapsulation layer disposed on the first encapsulation layer, overlapping the element layer 130 and including an organic insulating material, and a third encapsulation layer disposed on the second encapsulation layer and including an inorganic insulating material.

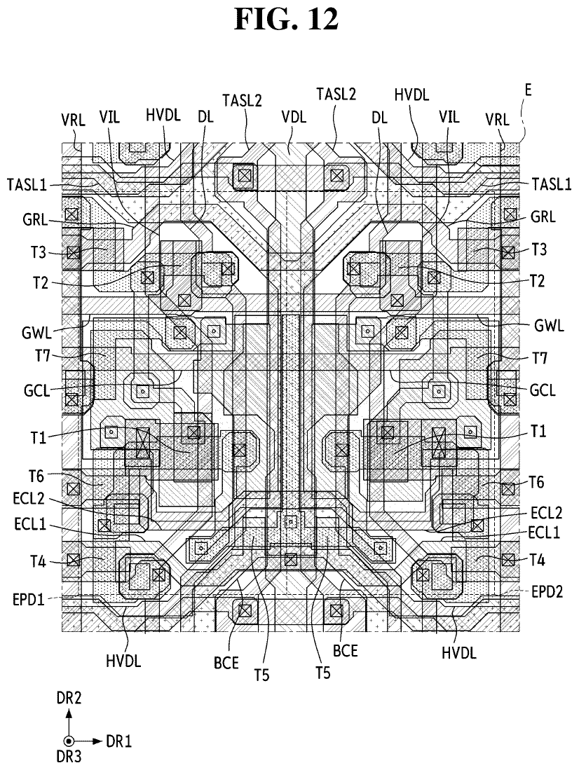

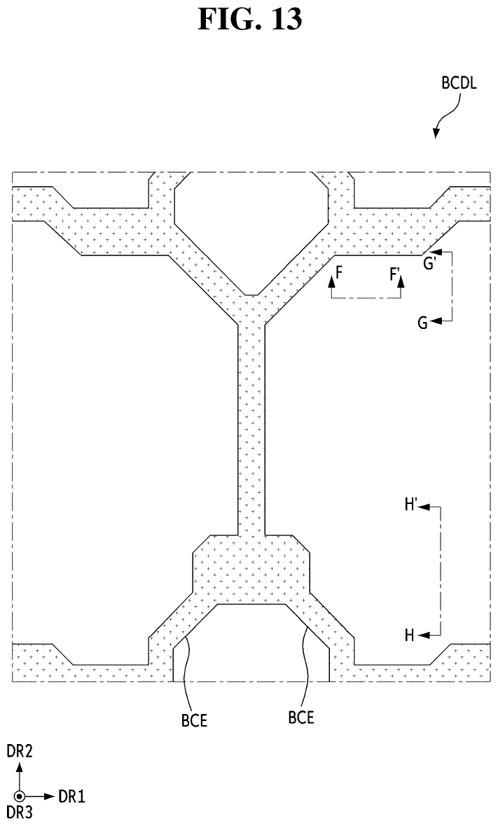

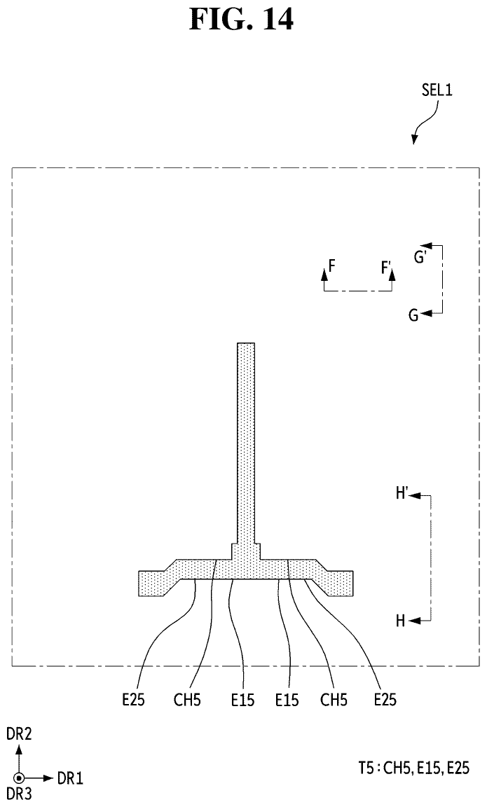

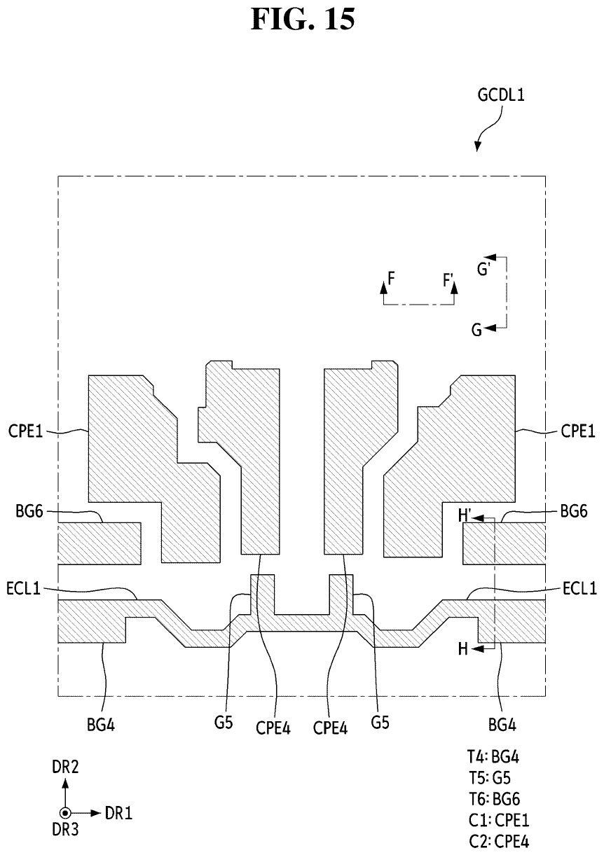

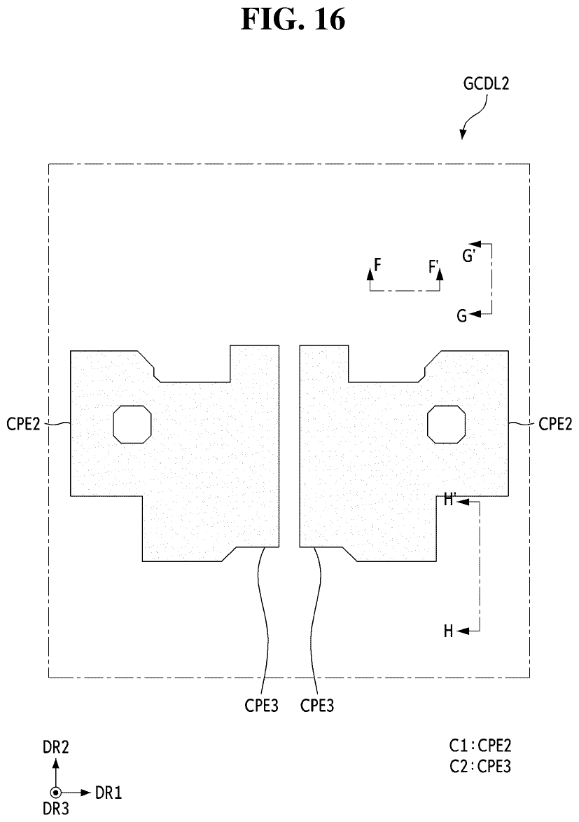

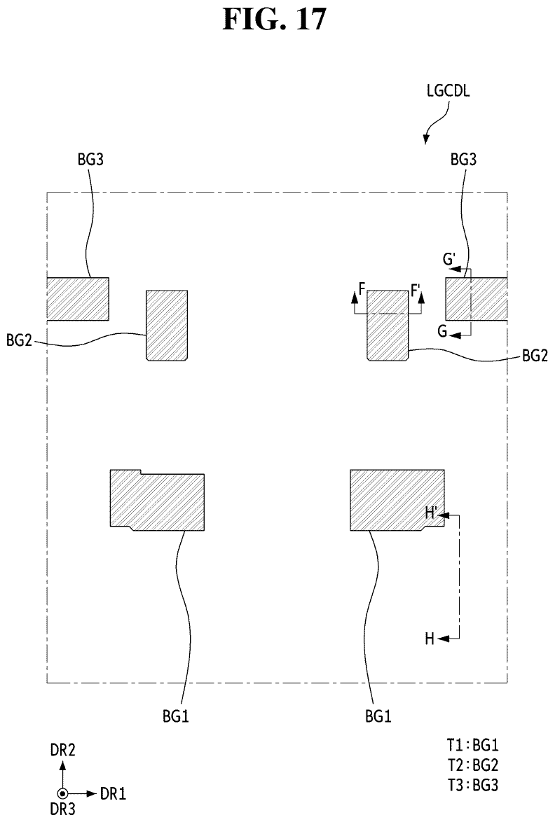

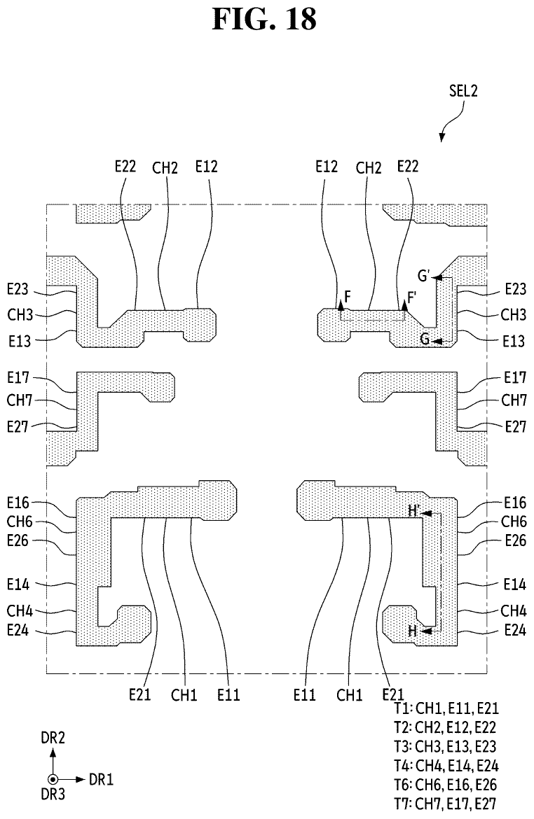

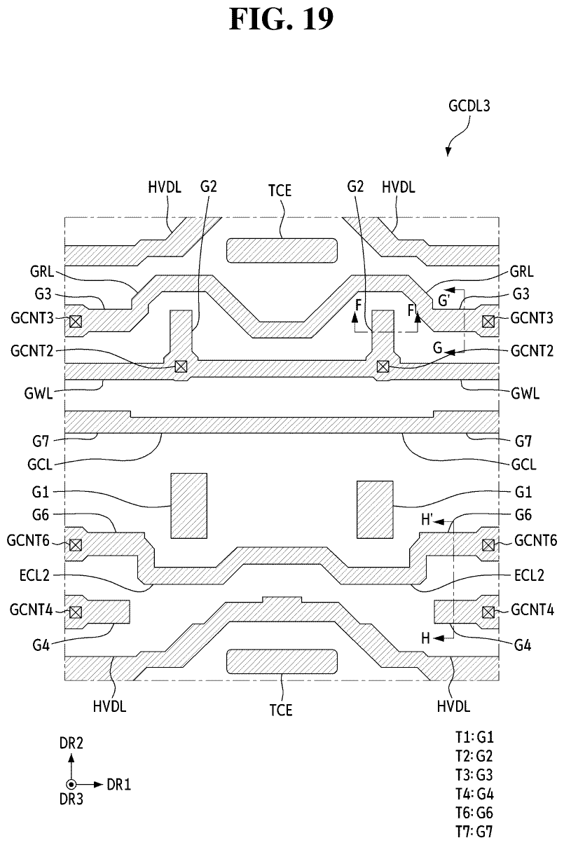

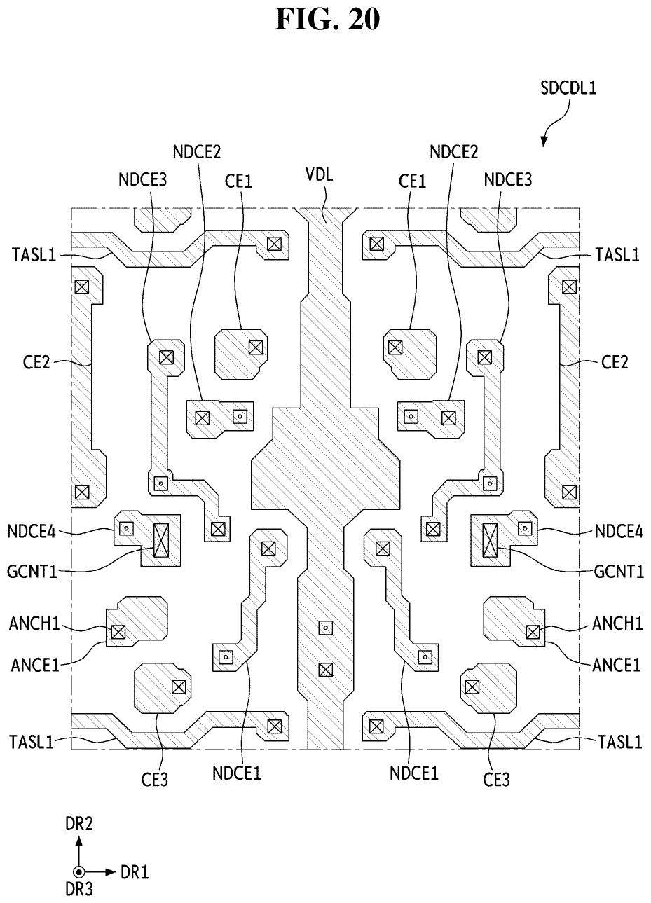

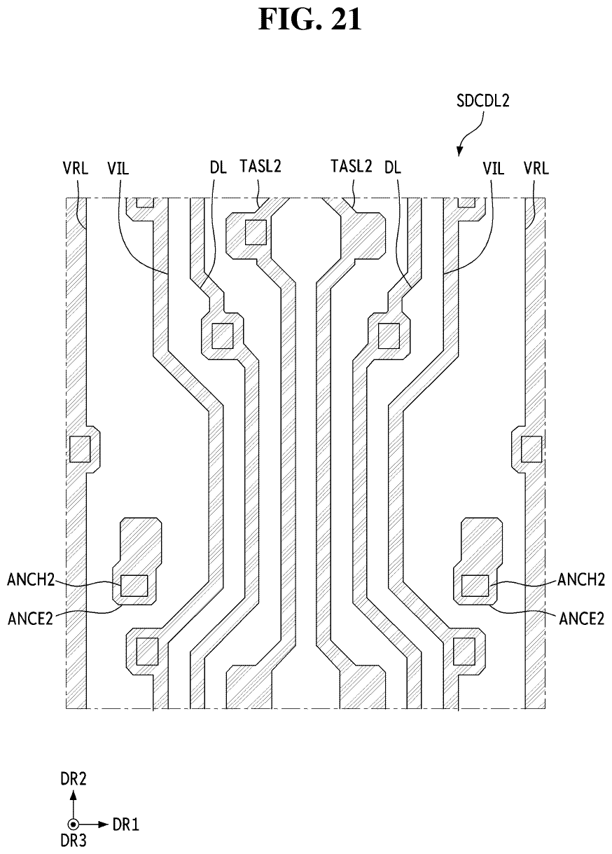

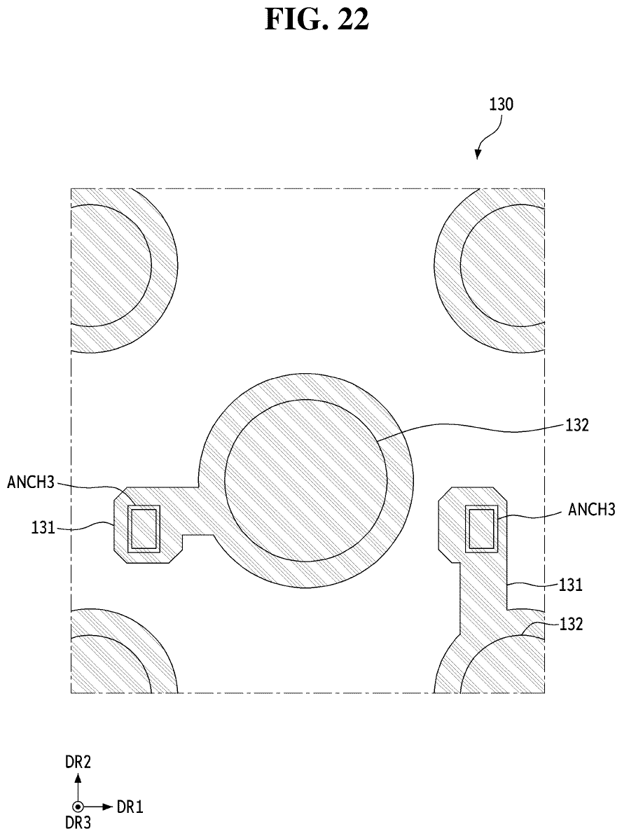

FIG. 12 is a layout diagram illustrating the circuit layer of part E of FIG. 10. FIG. 13 is a layout diagram illustrating a lower conductive layer of the circuit layer according to an embodiment. FIG. 14 is a layout diagram illustrating a first semiconductor layer of the circuit layer according to an embodiment. FIG. 15 is a layout diagram illustrating a first gate conductive layer of the circuit layer according to an embodiment. FIG. 16 is a layout diagram illustrating a second gate conductive layer of the circuit layer according to an embodiment. FIG. 17 is a layout diagram illustrating a lower gate conductive layer of the circuit layer according to an embodiment. FIG. 18 is a layout diagram illustrating the second semiconductor layer of the circuit layer according to an embodiment. FIG. 19 is a layout diagram illustrating a gate contact hole group and a third gate conductive layer of the circuit layer according to an embodiment. FIG. 20 is a layout diagram illustrating a gate contact hole group, a first contact hole group, a second contact hole group, and a first source-drain conductive layer of the circuit layer according to an embodiment. FIG. 21 is a layout diagram illustrating a first via hole group and a second source-drain conductive layer of the circuit layer according to an embodiment. FIG. 22 is a layout diagram illustrating a second via hole group, an anode electrode, and a pixel defining layer according to an embodiment.

Referring to FIGS. 12 to 22 with reference to FIGS. 7 and 11, the display panel 100 may include the substrate 110, the circuit layer 120, and the element layer 130.

Since the description of the substrate 110 and the element layer 130 has been made above with reference to FIG. 11 or the like, the circuit layer 120 will be described in detail below.

The circuit layer 120 may include the lower conductive layer BCDL, the first buffer layer 121, the first semiconductor layer SEL1, the first gate insulating layer 122, the first gate conductive layer GCDL1, the first interlayer insulating layer 123, the second gate conductive layer GCDL2, the second interlayer insulating layer 124, the lower gate conductive layer LGCDL, the second buffer layer 125, the second semiconductor layer SEL2, the second gate insulating layer 126, the third gate conductive layer GCDL3, the third interlayer insulating layer 127, the first source-drain conductive layer SDCDL1, the first planarization layer 128, the second source-drain conductive layer SDCDL2, and the second planarization layer 129.

The lower conductive layer BCDL may be disposed on the substrate 110. The lower conductive layer BCDL may include a single layer or multiple layers containing any one of molybdenum (Mo), aluminum (Al), chromium (Cr), gold (Au), titanium (Ti), nickel (Ni), neodymium (Nd) and copper (Cu) or an alloy thereof.

As illustrated in FIG. 13, the lower conductive layer BCDL may include the lower electrode BCE.

The first buffer layer 121 may be disposed on the lower conductive layer BCDL. The first buffer layer 121 may cover the lower conductive layer BCDL and the substrate 110. For example, the first buffer layer 121 may be disposed on the entire surface of the substrate 110. The first buffer layer 121 may insulate the lower conductive layer BCDL from the first semiconductor layer SEL1.

The first buffer layer 121 may protect the transistors of the circuit layer 120 and the light emitting layer 133 of the element layer 130 from moisture permeating through the substrate 110 that is susceptible to moisture permeation. The first buffer layer 121 may include a plurality of inorganic films that are alternately stacked. For example, the first buffer layer 121 may include a single film or multiple films in which one or more inorganic films including a silicon nitride layer, a silicon oxynitride layer, a silicon oxide layer, a titanium oxide layer or an aluminum oxide layer are alternately stacked.

The first semiconductor layer SEL1 may be disposed on the first buffer layer 121. The first semiconductor layer SEL1 may include polycrystalline silicon, monocrystalline silicon, low-temperature polycrystalline silicon, amorphous silicon, or an oxide semiconductor material. For example, as described above with reference to FIG. 11, the first semiconductor layer SEL1 may include a silicon semiconductor material such as polysilicon or amorphous silicon.

As illustrated in FIG. 14, the first semiconductor layer SEL1 may include the channel portion CH5, the first electrode E15, and the second electrode E25 of the fifth transistor T5.

The first gate insulating layer 122 may be disposed on the first semiconductor layer SEL1. The first gate insulating layer 122 may cover the first semiconductor layer SEL1 and the first buffer layer 121. The first gate insulating layer 122 may insulate the first semiconductor layer SEL1 from the first gate conductive layer GCDL1.

The first gate insulating layer 122 may include an inorganic film, for example, a silicon nitride layer, a silicon oxynitride layer, a silicon oxide layer, a titanium oxide layer, or an aluminum oxide layer.

The first gate conductive layer GCDL1 may be disposed on the first gate insulating layer 122. The first gate conductive layer GCDL1 may include a single layer or multiple layers containing any one of molybdenum (Mo), aluminum (Al), chromium (Cr), gold (Au), titanium (Ti), nickel (Ni), neodymium (Nd) and copper (Cu) or an alloy thereof.

As illustrated in FIG. 15, the first gate conductive layer GCDL1 may include a gate additional electrode BG4 of the fourth transistor T4, the gate electrode G5 of the fifth transistor T5, the gate additional electrode BG6 of the sixth transistor T6, the first capacitor electrode CPE1 of the first capacitor C1, the fourth capacitor electrode CPE4 of the second capacitor C2, and a first emission control line ECL1.

The first interlayer insulating layer 123 may be disposed on the first gate conductive layer GCDL1. The first interlayer insulating layer 123 may cover the first gate conductive layer GCDL1 and the first gate insulating layer 122. The first interlayer insulating layer 123 may insulate the first gate conductive layer GCDL1 from the second gate conductive layer GCDL2.

The first interlayer insulating layer 123 may include an inorganic film, for example, a silicon nitride layer, a silicon oxynitride layer, a silicon oxide layer, a titanium oxide layer, or an aluminum oxide layer.

The second gate conductive layer GCDL2 may be disposed on the first interlayer insulating layer 123. The second gate conductive layer GCDL2 may include a single layer or multiple layers containing any one of molybdenum (Mo), aluminum (Al), chromium (Cr), gold (Au), titanium (Ti), nickel (Ni), neodymium (Nd) and copper (Cu) or an alloy thereof.

As illustrated in FIG. 16, the second gate conductive layer GCDL2 may include the second capacitor electrode CPE2 of the first capacitor C1 and the third capacitor electrode CPE3 of the second capacitor C2.

The second interlayer insulating layer 124 may be disposed on the second gate conductive layer GCDL2. The second interlayer insulating layer 124 may cover the second gate conductive layer GCDL2 and the first interlayer insulating layer 123. The second interlayer insulating layer 124 may insulate the second gate conductive layer GCDL2 from the lower gate conductive layer LGCDL.

The second interlayer insulating layer 124 may include an inorganic film, for example, a silicon nitride layer, a silicon oxynitride layer, a silicon oxide layer, a titanium oxide layer, or an aluminum oxide layer.

The lower gate conductive layer LGCDL may be disposed on the second interlayer insulating layer 124. The lower gate conductive layer LGCDL may include a single layer or multiple layers containing any one of molybdenum (Mo), aluminum (Al), chromium (Cr), gold (Au), titanium (Ti), nickel (Ni), neodymium (Nd) and copper (Cu) or an alloy thereof.

As illustrated in FIG. 17, the lower gate conductive layer LGCDL may include the gate additional electrode BG1 of the first transistor T1, a gate additional electrode BG2 of the second transistor T2, and a gate additional electrode BG3 of the third transistor T3.

The second buffer layer 125 may be disposed on the lower gate conductive layer LGCDL. The second buffer layer 125 may cover the lower gate conductive layer LGCDL and the second interlayer insulating layer 124. The second buffer layer 125 may insulate the lower gate conductive layer LGCDL from the second semiconductor layer SEL2.

The second buffer layer 125 may include a single film or multiple films in which one or more inorganic films including a silicon nitride layer, a silicon oxynitride layer, a silicon oxide layer, a titanium oxide layer or an aluminum oxide layer are alternately stacked.

The second semiconductor layer SEL2 may be disposed on the second buffer layer 125. The second semiconductor layer SEL2 may include polycrystalline silicon, monocrystalline silicon, low-temperature polycrystalline silicon, amorphous silicon, or an oxide semiconductor material. For example, as described above with reference to FIG. 11, the second semiconductor layer SEL2 may include an oxide semiconductor material.

As illustrated in FIG. 18, the second semiconductor layer SEL2 may include the channel portion CH1, the first electrode E11 and the second electrode E21 of the first transistor T1, a channel portion CH2, a first electrode E12 and a second electrode E22 of the second transistor T2, a channel portion CH3, a first electrode E13 and a second electrode E23 of the third transistor T3, a channel portion CH4, a first electrode E14 and a second electrode E24 of the fourth transistor T4, the channel portion CH6, the first electrode E16 and the second electrode E26 of the sixth transistor T6, and a channel portion CH7, a first electrode E17 and a second electrode E27 of the seventh transistor T7.

The second gate insulating layer 126 may be disposed on the second semiconductor layer SEL2. The second gate insulating layer 126 may cover the second semiconductor layer SEL2. The second gate insulating layer 126 may insulate the second semiconductor layer SEL2 from the third gate conductive layer GCDL3.

The second gate insulating layer 126 may include an inorganic film, for example, a silicon nitride layer, a silicon oxynitride layer, a silicon oxide layer, a titanium oxide layer, or an aluminum oxide layer.

The third gate conductive layer GCDL3 may be disposed on the second gate insulating layer 126. The third gate conductive layer GCDL3 may include a single layer or multiple layers containing any one of molybdenum (Mo), aluminum (Al), chromium (Cr), gold (Au), titanium (Ti), nickel (Ni), neodymium (Nd) and copper (Cu) or an alloy thereof.

As illustrated in FIG. 19, the third gate conductive layer GCDL3 may include a gate electrode G1 of the first transistor T1, a gate electrode G2 of the second transistor T2, a gate electrode G3 of the third transistor T3, a gate electrode G4 of the fourth transistor T4, the gate electrode G6 of the sixth transistor T6, a gate electrode G7 of the seventh transistor T7, a first horizontal power line HVDL, an auxiliary line connection electrode TCE, the reset control line GRL, the scan write line GWL, the gate control line GCL, the second emission control line ECL2, and a gate contact hole group.

The gate contact hole group may include contact holes extending downwardly from the third gate conductive layer GCDL3. For example, the gate contact hole group may include a second gate contact hole GCNT2, a third gate contact hole GCNT3, a fourth gate contact hole GCNT4, and a sixth gate contact hole GCNT6.

The third interlayer insulating layer 127 may be disposed on the third gate conductive layer GCDL3. The third interlayer insulating layer 127 may cover the third gate conductive layer GCDL3 and the second gate insulating layer 126. The third interlayer insulating layer 127 may insulate the third gate conductive layer GCDL3 from the first source-drain conductive layer SDCDL1.

The third interlayer insulating layer 127 may include an inorganic film, for example, a silicon nitride layer, a silicon oxynitride layer, a silicon oxide layer, a titanium oxide layer, or an aluminum oxide layer.

The first source-drain conductive layer SDCDL1 may be disposed on the third interlayer insulating layer 127. The first source-drain conductive layer SDCDL1 may include a single layer or multiple layers containing any one of molybdenum (Mo), aluminum (Al), chromium (Cr), gold (Au), titanium (Ti), nickel (Ni), neodymium (Nd) and copper (Cu) or an alloy thereof.

As illustrated in FIG. 20, the first source-drain conductive layer SDCDL1 may include the first power line VDL, the first transmission auxiliary line TASL1, first to third connection electrodes CE1 to CE3, the first to fourth node connection electrodes NDCE1 to NDCE4, the first anode connection electrode ANCE1, the first anode contact hole ANCH1, a first contact hole group, a second contact hole group, and a gate contact hole group.

The first contact hole group may include contact holes extending downwardly from the first source-drain conductive layer SDCDL1 to pass through the second interlayer insulating layer 124.

The second contact hole group may include contact holes extending downwardly from the first source-drain conductive layer SDCDL1 to pass through the second gate insulating layer 126. For example, the second contact hole group may include the first anode contact hole ANCH1.

The gate contact hole group may include contact holes extending downwardly from the first source-drain conductive layer SDCDL1. For example, the gate contact hole group may include a first gate contact hole GCNT1.

The first planarization layer 128 may be disposed on the first source-drain conductive layer SDCDL1. The first planarization layer 128 may cover the first source-drain conductive layer SDCDL1 and the third interlayer insulating layer 127. The first planarization layer 128 may cover the stepped portions caused by the layers located below the first planarization layer 128 and planarize an upper surface of the first planarization layer 128. The first planarization layer 128 may insulate the first source-drain conductive layer SDCDL1 from the second source-drain conductive layer SDCDL2.

The first planarization layer 128 may include an organic film such as acrylic resin, epoxy resin, phenolic resin, polyamide resin, polyimide resin or the like.

The second source-drain conductive layer SDCDL2 may be disposed on the first planarization layer 128. The second source-drain conductive layer SDCDL2 may include a single layer or multiple layers containing any one of molybdenum (Mo), aluminum (Al), chromium (Cr), gold (Au), titanium (Ti), nickel (Ni), neodymium (Nd) and copper (Cu) or an alloy thereof.

As illustrated in FIG. 21, the second source-drain conductive layer SDCDL2 may include the reference voltage line VRL, the initialization voltage line VIL, the data line DL, the second transmission auxiliary line TASL2, the second anode connection electrode ANCE2, and the first via hole group.

The first via hole group may include contact holes extending downwardly from the second source-drain conductive layer SDCDL2. For example, the first via hole group may include the second anode contact hole ANCH2.

The second planarization layer 129 may be disposed on the second source-drain conductive layer SDCDL2. The second planarization layer 129 may cover the second source-drain conductive layer SDCDL2 and the first planarization layer 128. The second planarization layer 129 may cover the stepped portions caused by the layers located below the second planarization layer 129 and planarize an upper surface of the second planarization layer 129. The second planarization layer 129 may insulate the second source-drain conductive layer SDCDL2 from the anode electrode 131.

The second planarization layer 129 may include an organic film such as acrylic resin, epoxy resin, phenolic resin, polyamide resin, polyimide resin or the like.

The element layer 130 may be disposed on the second planarization layer 129. As illustrated in FIG. 22, the element layer 130 may include the anode electrode 131, the pixel defining layer 132, and the second via hole group.

The second via hole group may include contact holes extending downwardly from the anode electrode 131. For example, the second via hole group may include the third anode contact hole ANCH3.

According to an embodiment, the pixel driver EPD may include a first pixel driver EPD1 and a second pixel driver EPD2. The first pixel driver EPD1 and the second pixel driver EPD2 may be arranged side by side in the first direction DR1.

According to an embodiment, as illustrated in FIG. 12, the first pixel driver EPD1 and the second pixel driver EPD2 may be substantially symmetrical with respect to the first power line VDL. The first pixel driver EPD1 and the second pixel driver EPD2 may share some components with each other. For example, the first pixel driver EPD1 and the second pixel driver EPD2 may share with each other the lower electrode BCE included in the lower conductive layer BCDL, the first electrode E15 of the fifth transistor T5 included in the first semiconductor layer SEL1, the auxiliary line connection electrode TCE included in the third gate conductive layer GCDL3, and the first power line VDL included in the first source-drain conductive layer SDCDL1.

The first pixel driver EPD1 may be connected to any one of the anode electrodes 131 illustrated in FIG. 22, and the second pixel driver EPD2 may be connected to another one of the anode electrodes 131 illustrated in FIG. 22.

Hereinafter, the lines arranged around the pixel driver EPD are described.

The scan write line GWL may extend in the first direction DR1. The scan write line GWL may receive the scan write signal GW from the gate driving circuit and supply the scan write signal GW to the pixel driver EPD. For example, as illustrated in FIG. 19, the scan write line GWL may be integrated with the gate electrode G2 of the second transistor T2, and may supply the scan write signal GW to the pixel driver EPD through the second gate electrode G2 of the second transistor T2.

The reset control line GRL may extend in the first direction DR1. The reset control line GRL may receive the reset control signal GR from the gate driving circuit and supply the reset control signal GR to the pixel driver EPD. For example, as illustrated in FIG. 19, the reset control line GRL may be integrated with the gate electrode G3 of the third transistor T3, and may supply the reset control signal GR to the pixel driver EPD through the gate electrode G3 of the third transistor T3.

The gate control line GCL may extend in the first direction DR1. The gate control line GCL may receive the gate control signal GC from the gate driving circuit and supply the gate control signal GC to the pixel driver EPD. For example, as illustrated in FIG. 19, the gate control line GCL may be integrated with the gate electrode G7 of the seventh transistor T7, and may supply the gate control signal GC to the pixel driver EPD through the gate electrode G7 of the seventh transistor T7.

The first emission control line ECL1 may extend in the first direction DR1. The first emission control line ECL1 may receive the first emission control signal EC1 from the gate driving circuit and supply the first emission control signal EC1 to the pixel driver EPD. For example, as illustrated in FIG. 15, the first emission control line ECL1 may be integrated with the gate electrode G5 of the fifth transistor T5, and may supply the first emission control signal EC1 to the pixel driver EPD through the gate electrode G5 of the fifth transistor T5.

The second emission control line ECL2 may extend in the first direction DR1. The second emission control line ECL2 may receive the second emission control signal EC2 from the gate driving circuit and supply the second emission control signal EC2 to the pixel driver EPD. For example, as illustrated in FIG. 19, the second emission control line ECL2 may be integrated with the gate electrode G6 of the sixth transistor T6, and may supply the second emission control signal EC2 to the pixel driver EPD through the gate electrode G6 of the sixth transistor T6.

The first horizontal power line HVDL may extend in the first direction DR1. As illustrated in FIGS. 19 and 20, the first horizontal power line HVDL may be connected to the first power line VDL through the contact holes of the second contact hole group. The first horizontal power line HVDL may receive the first power ELVDD from the first power line VDL.

The first transmission auxiliary line TASL1 may extend in the first direction DR1. The first transmission auxiliary line TASL1 may include a first sub-transmission auxiliary line disposed in one side, e.g., the left side, of the first power line VDL, and a second sub-transmission auxiliary line disposed in the other side, e.g., the right side, of the first power line VDL. As illustrated in FIGS. 19 and 20, the first sub-transmission auxiliary line and the second sub-transmission auxiliary line may be connected to each other through the auxiliary line connection electrode TCE included in the third gate conductive layer GCDL3 and the contact holes of the second contact hole group. As illustrated in FIGS. 20 and 21, the first transmission auxiliary line TASL1 may be connected to the second transmission auxiliary line TASL2 through the contact hole of the first via hole group. The first transmission auxiliary line TASL1 may be connected to one of the data lines DL or the power lines to reduce the width of the non-display area NDA or to lower the resistance of the path through which power or a constant voltage is transmitted, as described with reference to FIGS. 9 and 10.

The initialization voltage line VIL may extend in the second direction DR2. The initialization voltage line VIL may include a first initialization voltage line disposed in one side, e.g., the left side, of the first power line VDL, and a second initialization voltage line disposed in the other side, e.g., the right side, of the first power line VDL. The first initialization voltage line VIL disposed in a first side of the first power line VDL in the first direction DR1 may be connected to the first pixel driver EPD1, and the second initialization voltage line VIL disposed in a second side of the first power line VDL in the first direction DR1 may be connected to the second pixel driver EPD2.

The initialization voltage line VIL may receive the initialization voltage VINT from the power supply unit and supply the initialization voltage VINT to the pixel driver EPD. For example, as illustrated in FIGS. 18, 20, and 21, the initialization voltage line VIL may be connected to the second electrode E24 of the fourth transistor T4 through the contact hole of the first via hole group, the third connection electrode CE3 and the contact hole of the second contact hole group, and may supply the initialization voltage VINT to the pixel driver EPD through the second electrode E24 of the fourth transistor T4.

The data line DL may extend in the second direction DR2. The data line DL may include a first data line disposed in one side, e.g., the left side, of the first power line VDL, and a second data line disposed in the other side, e.g., the right side, of the first power line VDL. The first data line DL disposed in a first side of the first power line VDL in the first direction DR1 may be connected to the first pixel driver EPD1, and the second data line DL disposed in a second side of the first power line VDL in the first direction DR1 may be connected to the second pixel driver EPD2.

The data line DL may receive the data signal Vdata from the display driving circuit 200 and supply the data signal Vdata to the pixel driver EPD. For example, as illustrated in FIGS. 18, 20, and 21, the data line DL may be connected to the first electrode E12 of the second transistor T2 through the contact hole of the first via hole group, the first connection electrode CE1 and the contact hole of the second contact hole group, and may supply the data signal Vdata to the pixel driver EPD through the first electrode E12 of the second transistor T2.

The first power line VDL may extend in the second direction DR2. The first power line VDL may be located on the boundary between the first pixel driver EPD1 and the second pixel driver EPD2. The first pixel driver EPD1 and the second pixel driver EPD2 may share the first power line VDL with each other.

The first power line VDL may supply the first power ELVDD received from the power supply unit to the pixel driver EPD. For example, as illustrated in FIGS. 14 and 20, the first power line VDL may be connected to the first electrode E15 of the fifth transistor T5 through the contact hole of the first contact hole group, and may supply the first power ELVDD to the pixel driver EPD through the first electrode E15 of the fifth transistor T5.

Although not illustrated in the drawing, the second power line VSL may extend in the first direction DR1 or the second direction DR2. The second power line VSL may supply the second power ELVSS received from the power supply unit to the pixel driver EPD. For example, the second power line VSL may be connected to the cathode electrode 134 and supply the second power ELVSS to the light emitting element LE through the cathode electrode 134.

The reference voltage line VRL may extend in the second direction DR2. The reference voltage line VRL may include a first reference voltage line disposed in one side, e.g., the left side, of the first power line VDL, and a second reference voltage line disposed in the other side, e.g., the right side, of the first power line VDL. The first reference voltage line VRL disposed in a first side of the first power line VDL in the first direction DR1 may be connected to the first pixel driver EPD1, and the second reference voltage line VRL disposed in a second side of the first power line VDL in the first direction DR1 may be connected to the second pixel driver EPD2.

The reference voltage line VRL may supply the reference voltage VREF received from the power supply unit to the pixel driver EPD. For example, as illustrated in FIGS. 18, 20, and 21, the reference voltage line VRL may be connected to the second electrode E23 of the third transistor T3 and the second electrode E27 of the seventh transistor T7 through the contact hole of the first via hole group, the second connection electrode CE2 and the contact hole of the second contact hole group, and may supply the reference voltage VREF to the pixel driver EPD through the second electrode E23 of the third transistor T3 and the second electrode E27 of the seventh transistor T7.

The second transmission auxiliary line TASL2 may extend in the second direction DR2. The second transmission auxiliary line TASL2 may include at least two second transmission auxiliary lines TASL2. Each of at least two second transmission auxiliary lines TASL2 is disposed in one side, e.g., the left side, of the first power line VDL, or disposed in the other side, e.g., the right side, of the first power line VDL. The second transmission auxiliary line TASL2 disposed in a first side of the first power line VDL in the first direction DR1 may be connected to the first pixel driver EPD1, and the second transmission auxiliary line TASL2 disposed in a second side of the first power line VDL in the first direction DR1 may be connected to the second pixel driver EPD2.

The second transmission auxiliary line TASL2 may be connected to the first transmission auxiliary line TASL1 through the contact hole of the first via hole group. As described with reference to FIGS. 9 and 10, the second transmission auxiliary line TASL2 may be connected to one of the data lines DL or the power lines to reduce the width of the non-display area NDA or to lower the resistance of the path through which power or a constant voltage is transmitted.

The display device 10 according to an embodiment includes the first auxiliary lines ASL1 (see FIG. 9) including the first transmission auxiliary line TASL1, and the second auxiliary lines ASL2 (see FIG. 9) including the second transmission auxiliary line TASL2, so that the size of the non-display area NDA (see FIG. 8) may be reduced, and the high-resolution display device 10 may be implemented by densely arranging the pixels PX (see FIG. 5). In addition, since the first pixel driver EPD1 and the second pixel driver EPD2 share some lines and components, such as the first power line VDL, and the pixel circuits are arranged symmetrically with reference to the first power line VDL, the integration density of the display device 10 may be further increased.

Hereinafter, the first to seventh transistors T1 to T7, the first capacitor C1, and the second capacitor C2 of the pixel driver EPD are described.

The pixel driver EPD may include the first transistor T1, the second transistor T2, the third transistor T3, the fourth transistor T4, the fifth transistor T5, the sixth transistor T6, the seventh transistor T7, the first capacitor C1, and the second capacitor C2.

The first to seventh transistors T1 to T7 may include the channel portions CH1 to CH7, the first electrodes E11 to E17, the second electrodes E21 to E27, and the gate electrodes G1 to G7, respectively. Some of the first to seventh transistors T1 to T7 may further include the gate additional electrode. For example, the first, second, third, fourth and sixth transistors T1, T2, T3, T4 and T6 may include the gate additional electrodes BG1, BG2, BG3, BG4, and BG6.

The channel portion CH1 of the first transistor T1 may be included in the second semiconductor layer SEL2 and may overlap the gate electrode G1 of the first transistor T1.

The gate electrode G1 of the first transistor T1 may be included in the third gate conductive layer GCDL3. The gate electrode G1 of the first transistor T1 may be connected to the first capacitor electrode CPE1 of the first capacitor C1 through the third node connection electrode NDCE3. The gate electrode G1 of the first transistor T1 may be electrically connected to the second electrode E22 of the second transistor T2 through the third node connection electrode NDCE3.

The gate additional electrode BG1 of the first transistor T1 may be included in the lower gate conductive layer LGCDL. The gate additional electrode BG1 of the first transistor T1 may overlap the gate electrode G1 of the first transistor T1 and the channel portion CH1 of the first transistor T1.

The gate additional electrode BG1 of the first transistor T1 may be connected to the second electrode E21 of the first transistor T1 and the first electrode E16 of the sixth transistor T6 through the fourth node connection electrode NDCE4 and the first gate contact hole GCNT1 of the gate contact hole group. The gate additional electrode BG1 of the first transistor T1 may be connected to the second capacitor electrode CPE2 of the first capacitor C1 through the fourth node connection electrode NDCE4 and the contact hole of the first contact hole group.

The first electrode E11 and the second electrode E21 of the first transistor T1 may be included in the second semiconductor layer SEL2. The first electrode E11 and the second electrode E21 of the first transistor T1 may be formed by performing heat treatment on a part of the channel portion CH1 to make it conductive. The first electrode E11 and the second electrode E21 of the first transistor T1 may become conductive as an N-type semiconductor, but the present disclosure is not limited thereto.

The first electrode E11 of the first transistor T1 may be connected to the second electrode E25 of the fifth transistor T5 through the first node connection electrode NDE1. The first electrode E11 of the first transistor T1 may be provided with the first power ELVDD from the first power line VDL through the fifth transistor T5.

The second electrode E21 of the first transistor T1 may be connected to the second capacitor electrode CPE2 of the first capacitor C1 and the third capacitor electrode CPE3 of the second capacitor C2 through the fourth node connection electrode NCE4 and the contact hole of the first contact hole group. The second electrode E21 of the first transistor T1 may be connected to the gate additional electrode BG1 of the first transistor T1 through the fourth node connection electrode NCE4 and the first gate contact hole GCNT1 of the gate contact hole group. The second electrode E21 of the first transistor T1 may be integrated with the first electrode E16 of the sixth transistor T6.

The channel portion CH2 of the second transistor T2 may be included in the second semiconductor layer SEL2 and may overlap the gate electrode G2 of the second transistor T2.

The gate electrode G2 of the second transistor T2 may be included in the third gate conductive layer GCDL3. The gate electrode G2 of the second transistor T2 may be integrated with the scan write line GWL. The gate electrode G2 of the second transistor T2 may be provided with the scan write signal GW from the scan write line GWL.

The gate additional electrode BG2 of the second transistor T2 may be included in the lower gate conductive layer LGCDL. The gate additional electrode BG2 of the second transistor T2 may overlap the gate electrode G2 of the second transistor T2 and the channel portion CH2 of the second transistor T2.

The gate additional electrode BG2 of the second transistor T2 may be connected to the gate electrode G2 of the second transistor T2 and the scan write line GWL through the second gate contact hole GCNT2 of the gate contact hole group.

The first electrode E12 and the second electrode E22 of the second transistor T2 may be included in the second semiconductor layer SEL2. The first electrode E12 and the second electrode E22 of the second transistor T2 may be formed by performing heat treatment on a part of the channel portion CH2 to make it conductive. The first electrode E12 and the second electrode E22 of the second transistor T2 may become conductive as an N-type semiconductor, but the present disclosure is not limited thereto.

The first electrode E12 of the second transistor T2 may be connected to the data line DL through the first connection electrode CE1. The first electrode E12 of the second transistor T2 may be provided with the data signal Vdata from the data line DL.

The second electrode E22 of the second transistor T2 may be connected to the first capacitor electrode CPE1 of the first capacitor C1 through the third node connection electrode NDCE3 and the contact hole of the first contact hole group. The second electrode E22 of the second transistor T2 may be electrically connected to the gate electrode G1 of the first transistor T1 through the third node connection electrode NDCE3 and the contact hole of the second contact hole group. The second electrode E22 of the second transistor T2 may supply a gate voltage to the first transistor T1 through the third node connection electrode NDCE3.

The second electrode E22 of the second transistor T2 may be connected to the first electrode E13 of the third transistor T3. The second electrode E22 of the second transistor T2 may be integrated with the first electrode E13 of the third transistor T3.

The channel portion CH3 of the third transistor T3 may be included in the second semiconductor layer SEL2 and may overlap the gate electrode G3 of the third transistor T3.

The gate electrode G3 of the third transistor T3 may be included in the third gate conductive layer GCDL3. The gate electrode G3 of the third transistor T3 may be integrated with the reset control line GRL. The gate electrode G3 of the third transistor T3 may be provided with the reset control signal GR from the reset control line GRL.

The gate additional electrode BG3 of the third transistor T3 may be included in the lower gate conductive layer LGCDL. The gate additional electrode BG3 of the third transistor T3 may overlap the gate electrode G3 of the third transistor T3 and the channel portion CH3 of the third transistor T3.

The gate additional electrode BG3 of the third transistor T3 may be connected to the gate electrode G3 of the third transistor T3 and the reset control line GRL through the third gate contact hole GCNT3 of the gate contact hole group.

The first electrode E13 and the second electrode E23 of the third transistor T3 may be included in the second semiconductor layer SEL2. The first electrode E13 and the second electrode E23 of the third transistor T3 may be formed by performing heat treatment on a part of the channel portion CH3 to make it conductive. The first electrode E13 and the second electrode E23 of the third transistor T3 may become conductive as an N-type semiconductor, but the present disclosure is not limited thereto.

The first electrode E13 of the third transistor T3 may be connected to the second electrode E22 of the second transistor T2. The first electrode E13 of the third transistor T3 may be integrated with the second electrode E22 of the second transistor T2. The first electrode E13 of the third transistor T3 may be connected to the first capacitor electrode CPE1 of the first capacitor C1 through the third node connection electrode NDCE3 and the contact hole of the first contact hole group. The first electrode E13 of the third transistor T3 may be connected to the gate electrode G1 of the first transistor T1 through the third node connection electrode NDCE3 and the contact hole of the second contact hole group.

The second electrode E23 of the third transistor T3 may be connected to the reference voltage line VRL through the second connection electrode CE2. The second electrode E23 of the third transistor T3 may receive the reference voltage VREF from the reference voltage line VRL through the second connection electrode CE2.

The channel portion CH4 of the fourth transistor T4 may be disposed in the second semiconductor layer SEL2 and may overlap the gate electrode G4 of the fourth transistor T4.

The gate electrode G4 of the fourth transistor T4 may be disposed in the third gate conductive layer GCDL3. The gate electrode G4 of the fourth transistor T4 may be connected to the gate additional electrode BG4 of the fourth transistor T4 and the first emission control line ECL1 through the fourth gate contact hole GCNT4 of the gate contact hole group. The gate electrode G4 of the fourth transistor T4 may be provided with the first emission control signal EC1 from the first emission control line ECL1.

The gate additional electrode BG4 of the fourth transistor T4 may be included in the first gate conductive layer GCDL1. The gate additional electrode BG4 of the fourth transistor T4 may overlap the gate electrode G4 of the fourth transistor T4 and the channel portion CH4 of the fourth transistor T4.

The gate additional electrode BG4 of the fourth transistor T4 may be connected to the gate electrode G4 of the fourth transistor T4 through the fourth gate contact hole GCNT4 of the gate contact hole group. The gate additional electrode BG4 of the fourth transistor T4 may be connected to the first emission control line ECL1. The gate additional electrode BG4 of the fourth transistor T4 may be integrated with the first emission control line ECL1.

The first electrode E14 and the second electrode E24 of the fourth transistor T4 may be disposed in the second semiconductor layer SEL2. The first electrode E14 and the second electrode E24 of the fourth transistor T4 may be formed by performing heat treatment on a part of the channel portion CH4 to make it conductive. The first electrode E14 and the second electrode E24 of the fourth transistor T4 may become conductive as an N-type semiconductor, but the present disclosure is not limited thereto.

The first electrode E14 of the fourth transistor T4 may be connected to the second electrode E26 of the sixth transistor T6. The first electrode E14 of the fourth transistor T4 may be integrated with the second electrode E26 of the sixth transistor T6. The first electrode E14 of the fourth transistor T4 may be electrically connected to the anode electrode 131 through the first anode connection electrode ANCE1, the first anode contact hole ANCH1 of the second contact hole group, the second anode connection electrode ANCE2, and the second anode contact hole ANCH2 of the first via hole group.

The second electrode E24 of the fourth transistor T4 may be connected to the initialization voltage line VIL through the third connection electrode CE3, the contact hole of the second contact hole group, and the contact hole of the first via hole group. The second electrode E24 of the fourth transistor T4 may receive the initialization voltage VINT from the initialization voltage line VIL.

The channel portion CH5 of the fifth transistor T5 may be included in the first semiconductor layer SEL1 and may overlap the gate electrode G5 of the fifth transistor T5.

The gate electrode G5 of the fifth transistor T5 may be included in the first gate conductive layer GCDL1. The gate electrode G5 of the fifth transistor T5 may be connected to the first emission control line ECL1. The gate electrode G5 of the fifth transistor T5 may be integrated with the first emission control line ECL1. The gate electrode G5 of the fifth transistor T5 may be provided with the first emission control signal EC1 from the first emission control line ECL1.

The first electrode E15 and the second electrode E25 of the fifth transistor T5 may be included in the first semiconductor layer SEL1. The first electrode E15 and the second electrode E25 of the fifth transistor T5 may be formed by performing heat treatment on a part of the channel portion CH5 to make it conductive. The first electrode E15 and the second electrode E25 of the fifth transistor T5 may become conductive as a P-type semiconductor, but the present disclosure is not limited thereto.

The first electrode E15 of the fifth transistor T5 may be connected to the first power line VDL through the contact hole of the first contact hole group. The first electrode E15 of the fifth transistor T5 may be provided with the first power ELVDD from the first power line VDL through the contact hole of the first contact hole group.

The second electrode E25 of the fifth transistor T5 may be connected to the first electrode E11 of the first transistor T1 through the first node connection electrode NDCE1. The second electrode E25 of the fifth transistor T5 may provide the first power ELVDD provided from the first power line VDL to the first transistor T1 through the first node connection electrode NDCE1.

The channel portion CH6 of the sixth transistor T6 may be included in the second semiconductor layer SEL2 and may overlap the gate electrode G6 of the sixth transistor T6.

The gate electrode G6 of the sixth transistor T6 may be included in the third gate conductive layer GCDL3. The gate electrode G6 of the sixth transistor T6 may be connected to the second emission control line ECL2. The gate electrode G6 of the sixth transistor T6 may be integrated with the second emission control line ECL2. The gate electrode G6 of the sixth transistor T6 may be provided with the second emission control signal EC2 from the second emission control line ECL2.

The gate additional electrode BG6 of the sixth transistor T6 may be included in the first gate conductive layer GCDL1. The gate additional electrode BG6 of the sixth transistor T6 may overlap the gate electrode G6 of the sixth transistor T6 and the channel portion CH6 of the sixth transistor T6.

The gate additional electrode BG6 of the sixth transistor T6 may be connected to the gate electrode G6 of the sixth transistor T6 and the second emission control line ECL2 through the sixth gate contact hole GCNT6 of the gate contact hole group.

The first electrode E16 and the second electrode E26 of the sixth transistor T6 may be included in the second semiconductor layer SEL2. The first electrode E16 and the second electrode E26 of the sixth transistor T6 may be formed by performing heat treatment on a part of the channel portion CH6 to make it conductive. The first electrode E16 and the second electrode E26 of the sixth transistor T6 may become conductive as an N-type semiconductor, but the present disclosure is not limited thereto.

The first electrode E16 of the sixth transistor T6 may be connected to the second capacitor electrode CPE2 of the first capacitor C1 and the third capacitor electrode CPE3 of the second capacitor C2 through the first gate contact hole GCNT1 of the gate contact hole group, the fourth node connection electrode NDCE4, and the contact hole of the first contact hole group. The first electrode E16 of the sixth transistor T6 may be connected to the gate additional electrode BG1 of the first transistor T1 through the first gate contact hole GCNT1 of the gate contact hole group and the fourth node connection electrode NDCE4. The first electrode E16 of the sixth transistor T6 may be connected to the second electrode E21 of the first transistor T1. The first electrode E16 of the sixth transistor T6 may be integrated with the second electrode E21 of the first transistor T1.

The second electrode E26 of the sixth transistor T6 may be electrically connected to the anode electrode 131 of the light emitting element LE through the first anode connection electrode ANCE1, the first anode contact hole ANCH1 of the second contact hole group, the second anode connection electrode ANCE2, the second anode contact hole ANCH2 of the first via hole group, and the third anode contact hole ANCH3 of the second via hole group. The second electrode E26 of the sixth transistor T6 may supply driving current to the light emitting element ED through the anode electrode 131. The second electrode E26 of the sixth transistor T6 may be connected to the first electrode E14 of the fourth transistor T4. The second electrode E26 of the sixth transistor T6 may be integrated with the first electrode E14 of the fourth transistor T4.

The channel portion CH7 of the seventh transistor T7 may be included in the second semiconductor layer SEL2 and may overlap the gate electrode G7 of the seventh transistor T7.

The gate electrode G7 of the seventh transistor T7 may be included in the third gate conductive layer GCDL3. The gate electrode G7 of the seventh transistor T7 may be connected to the gate control line GCL. The gate electrode G7 of the seventh transistor T7 may be integrated with the gate control line GCL. The gate electrode G7 of the seventh transistor T7 may be provided with the gate control signal GC from the gate control line GCL.

The first electrode E17 and the second electrode E27 of the seventh transistor T7 may be included in the second semiconductor layer SEL2. The first electrode E17 and the second electrode E27 of the seventh transistor T7 may be formed by performing heat treatment on a part of the channel portion CH7 to make it conductive. The first electrode E17 and the second electrode E27 of the seventh transistor T7 may become conductive as an N-type semiconductor, but the present disclosure is not limited thereto.

The first electrode E17 of the seventh transistor T7 may be connected to the fourth capacitor electrode CPE4 of the second capacitor C2 through the contact hole of the second contact hole group, the second node connection electrode NDCE2, and the contact hole of the first contact hole group.

The second electrode E27 of the seventh transistor T7 may be connected to the reference voltage line VRL through the contact hole of the second contact hole group, the second connection electrode CE2, and the contact hole of the first via hole group. The second electrode E27 of the seventh transistor T7 may be provided with the reference voltage VREF from the reference voltage line VRL.

The first capacitor C1 may include the first capacitor electrode CPE1 and the second capacitor electrode CPE2.

The first capacitor electrode CPE1 of the first capacitor C1 may be included in the first gate conductive layer GCDL1. The first capacitor electrode CPE1 of the first capacitor C1 may be connected to the gate electrode G1 of the first transistor T1, the second electrode E22 of the second transistor T2, and the first electrode E13 of the third transistor T3 through the third node connection electrode NDCE3.

The second capacitor electrode CPE2 of the first capacitor C1 may be included in the second gate conductive layer GCDL2. The second capacitor electrode CPE2 of the first capacitor C1 may be connected to the second electrode E21 of the first transistor T1, the gate additional electrode BG1 of the first transistor T1, and the first electrode E16 of the sixth transistor T6 through the fourth node connection electrode NCE4. The second capacitor electrode CPE2 of the first capacitor C1 may be connected to the third capacitor electrode CPE3 of the second capacitor C2. The second capacitor electrode CPE2 of the first capacitor C1 may be integrated with the third capacitor electrode CPE3 of the second capacitor C2.

The second capacitor C2 may include the third capacitor electrode CPE3 and the fourth capacitor electrode CPE4.

The third capacitor electrode CPE3 of the second capacitor C2 may be included in the second gate conductive layer GCDL2. The third capacitor electrode CPE3 of the second capacitor C2 may be connected to the second electrode E21 of the first transistor T1, the gate additional electrode BG1 of the first transistor T1, and the first electrode E16 of the sixth transistor T6 through the fourth node connection electrode NCE4. The third capacitor electrode CPE3 of the second capacitor C2 may be connected to the second capacitor electrode CPE2 of the first capacitor C1. The third capacitor electrode CPE3 of the second capacitor C2 may be integrated with the second capacitor electrode CPE2 of the first capacitor C1.

The fourth capacitor electrode CPE4 of the second capacitor C2 may be included in the first gate conductive layer GCDL1. The fourth capacitor electrode CPE4 of the second capacitor C2 may be connected to the first electrode E17 of the seventh transistor T7 through the second node connection electrode NDCE2.

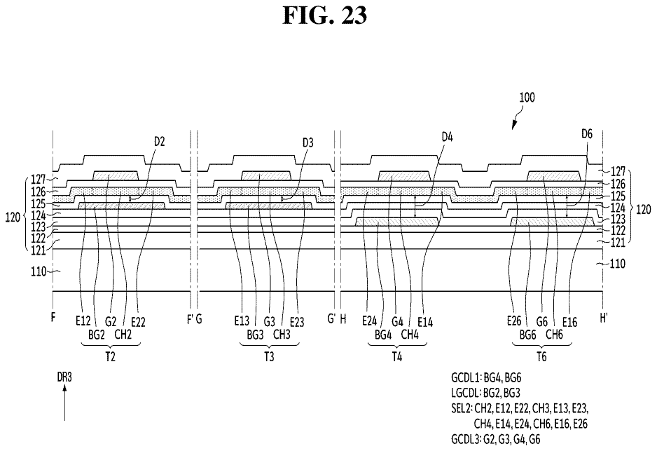

FIG. 23 is a cross-sectional view taken along lines F-F′, G-G′, and H-H′ of FIGS. 13 to 19.

Referring to FIG. 23 with reference to FIGS. 7 and 11 to 22, the gate electrodes G2, G3, G4, and G6 of the second, third, fourth, and sixth transistors T2, T3, T4, and T6 may be included in the third gate conductive layer GCDL3. The channel portions CH2, CH3, CH4, and CH6, the first electrodes E12, E13, E14, and E16, and the second electrodes E22, E23, E24, and E26 of the second, third, fourth, and sixth transistors T2, T3, T4, and T6 may be included in the second semiconductor layer SEL2.

As illustrated in FIG. 11, the gate electrode G1 of the first transistor T1 may also be included in the third gate conductive layer GCDL3, and the channel portion CH1, the first electrode E11 and the second electrode E21 of the first transistor T1 may also be located in the second semiconductor layer SEL2.

As illustrated in FIGS. 11 and 23, the gate additional electrode BG2 of the second transistor T2 and the gate additional electrode BG3 of the third transistor T3 may be disposed on the same layer as the gate additional electrode BG1 of the first transistor T1. For example, the gate additional electrodes BG1, BG2, and BG3 of the first to third transistors T1, T2, and T3 may be included in the lower gate conductive layer LGCDL.

In the present disclosure, when the layer positioned directly above and below the first layer is the same as the layer positioned directly above and below the second layer, the first layer and the second layer may be regarded as being disposed on the same layer.

The gate additional electrodes BG1, BG2, and BG3 of the first to third transistors T1, T2, and T3 may be disposed on a layer different from the gate electrode G5 of the fifth transistor T5, the first capacitor electrode CPE1 of the first capacitor C1, the fourth capacitor electrode CPE4 of the second capacitor C2, the second capacitor electrode CPE2 of the first capacitor C1, and the third capacitor electrode CPE3 of the second capacitor C2. For example, while the gate additional electrodes BG1, BG2, and BG3 of the first to third transistors T1, T2, and T3 may be included in the lower gate conductive layer LGCDL, the gate electrode G5 of the fifth transistor T5, the first capacitor electrode CPE1 of the first capacitor C1, and the fourth capacitor electrode CPE4 of the second capacitor C2 may be included in the first gate conductive layer GCDL1, and the second capacitor electrode CPE2 of the first capacitor C1 and the third capacitor electrode CPE3 of the second capacitor C2 may be included in the second gate conductive layer GCDL2.

According to an embodiment, first to third distances D1, D2, and D3, which are distances in the third direction DR3 between the gate additional electrodes BG1, BG2, and BG3 of the first to third transistors T1, T2, and T3 and the channel portions CH1, CH2, and CH3 of the first to third transistors T1, T2, and T3, may be less than fourth and sixth distances D4 and D6, which are distances in the third direction DR3 between the gate additional electrodes BG4 and BG6 of the fourth and sixth transistors T4 and T6 and the channel portions CH4 and CH6 of the fourth and sixth transistors T4 and T6.

As the first to third distances D1, D2, and D3 decrease, the penetration depth of the gate contact hole may decrease. Thus, the area of each of the first to third gate contact holes GCNT1, GCNT2, and GCNT3 in a plan view may be smaller than the area of each of the fourth and sixth gate contact holes GCNT4 and GCNT6 in a plan view. Accordingly, the area of the conductive layer above the first to third gate contact holes GCNT1, GCNT2, and GCNT3 (for example, the conductive layer above the first gate contact hole GCNT1 may be the first source-drain conductive layer SDCDL1, and the conductive layer above the second and third gate contact holes GCNT2 and GCNT3 may be the third gate conductive layer GCDL3) in a plan view may be minimized, thereby improving the integration density of the circuit layer 120.

According to an embodiment, the penetration depth of the first gate contact hole GCNT1 may be greater than the penetration depths of the second and third gate contact holes GCNT2 and GCNT3. For example, while the first gate contact hole GCNT1 is connected from the first source-drain conductive layer SDCDL1 to the top surface of the lower gate conductive layer LGCDL, the second and third gate contact holes GCNT2 and GCNT3 are connected from the third gate conductive layer GCDL3 to the top surface of the lower gate conductive layer LGCDL. Thus, the penetration depth of the first gate contact hole GCNT1 may be greater than the penetration depths of the second and third gate contact holes GCNT2 and GCNT3. Accordingly, the area of the second and third gate contact holes GCNT2 and GCNT3 in a plan view may be smaller than the area of the first gate contact hole GCNT1 in a plan view.

The display device 10 according to an embodiment further includes the lower gate conductive layer LGCDL, which includes the gate additional electrodes BG1, BG2, and BG3 of the first to third transistors T1, T2, and T3 and is a separate conductive layer from the first gate conductive layer GCDL1 and the second gate conductive layer GCDL2, thereby reducing the first to third distances D1, D2, and D3. Accordingly, the distance between the gate additional electrode BG1, BG2, and BG3 and the channel portion CH1, CH2, and CH3 is reduced to increase the electric field intensity, thereby improving the switching characteristics of the transistor, enabling the low power operation, reducing the leakage current, and increasing the response speed.

As not only the gate additional electrode BG1 of the first transistor T1 but also the gate additional electrodes BG2 and BG3 of the second and third transistors T2 and T3 are included in the lower gate conductive layer LGCDL, the pattern density of the lower gate conductive layer LGCDL may be improved as illustrated in FIG. 17. An increase in pattern density means that the area in which the electrodes of the lower gate conductive layer LGCDL are located has increased relative to the area of a unit area (the area of the unit pixel driver EPD).

As the pattern density of the lower gate conductive layer LGCDL increases, the number of electrodes (patterns) that is used to determine the relative positions during the electrode pattern formation process increases, thereby improving the accuracy and precision of the manufacturing process of the display device. In addition, this increased pattern density of the lower gate conductive layer LGCDL may prevent the pattern density of the first and second gate conductive layers GCDL1 and GCDL2 from being excessively arranged densely, thereby minimizing the occurrence of short circuits between adjacent electrodes.

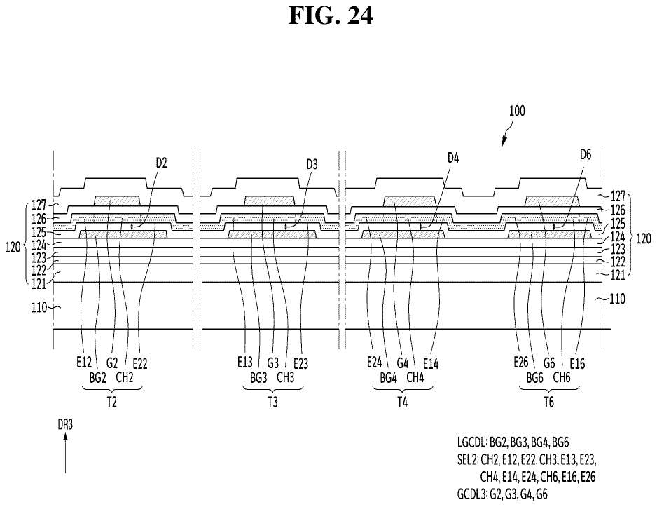

Hereinafter, an embodiment of the display device will be further described with reference to FIG. 24. In the following embodiment, description of the same components as those described above, which are denoted using the same or similar reference numerals, will be omitted or simplified, and differences will be mainly described.

FIG. 24 is a cross-sectional view illustrating cross-sections of a second transistor, a third transistor, a fourth transistor, and a sixth transistor of a display device according to an embodiment.

Referring to FIG. 24, the display device 10 according to an embodiment may include the gate additional electrodes BG4 and BG6 of the fourth and sixth transistors T4 and T6 which are included in the lower gate conductive layer LGCDL.

In the display device 10 according to an embodiment, the gate additional electrodes BG4 and BG6 of the fourth and sixth transistors T4 and T6 may be included in the lower gate conductive layer LGCDL. That is, the gate additional electrodes BG4 and BG6 of the fourth and sixth transistors T4 and T6 may be disposed on the same layer as the gate additional electrodes BG1, BG2, and BG3 of the first to third transistors T1, T2, and T3. Accordingly, the fourth and sixth distances D4 and D6 may be substantially equal to the first to third distances D1, D2, and D3.

The gate additional electrodes BG4 and BG6 of the fourth and sixth transistors T4 and T6 may be disposed on a layer different from the gate electrode G5 of the fifth transistor T5, the first capacitor electrode CPE1 of the first capacitor C1, the fourth capacitor electrode CPE4 of the second capacitor C2, the second capacitor electrode CPE2 of the first capacitor C1, and the third capacitor electrode CPE3 of the second capacitor C2. For example, while the gate additional electrodes BG4 and BG6 of the fourth and sixth transistors T4 and T6 may be included in the lower gate conductive layer LGCDL, the gate electrode G5 of the fifth transistor T5, the first capacitor electrode CPE1 of the first capacitor C1, and the fourth capacitor electrode CPE4 of the second capacitor C2 may be included in the first gate conductive layer GCDL1, and the second capacitor electrode CPE2 of the first capacitor C1 and the third capacitor electrode CPE3 of the second capacitor C2 may be included in the second gate conductive layer GCDL2.

As the fourth and sixth distances D4 and D6 decrease, the penetration depth of the gate contact hole may decrease, thereby reducing the area of the fourth and sixth gate contact holes GCNT4 and GCNT6 in a plan view.

According to an embodiment, the penetration depth of the first gate contact hole GCNT1 may be greater than the penetration depths of the fourth and sixth gate contact holes GCNT4 and GCNT6. For example, while the first gate contact hole GCNT1 is connected from the first source-drain conductive layer SDCDL1 to the top surface of the lower gate conductive layer LGCDL, the fourth and sixth gate contact holes GCNT4 and GCNT6 are connected from the third gate conductive layer GCDL3 to the top surface of the lower gate conductive layer LGCDL. Thus, the penetration depth of the first gate contact hole GCNT1 may be greater than the penetration depths of the fourth and sixth gate contact holes GCNT4 and GCNT6. Accordingly, the area of the fourth and sixth gate contact holes GCNT4 and GCNT6 in a plan view may be smaller than the area of the first gate contact hole GCNT1 in a plan view.

The display device 10 according to an embodiment further includes the lower gate conductive layer LGCDL, which includes the gate additional electrodes BG4 and BG6 of the fourth and sixth transistors T4 and T6 and is a separate conductive layer than the first gate conductive layer GCDL1 and the second gate conductive layer GCDL2, thereby reducing the fourth and sixth distances D4 and D6. Accordingly, the distance between the gate additional electrode G4, and G6 and the channel portion CH4, and CH6 is reduced to increase the electric field intensity, thereby improving the switching characteristics of the transistor, enabling the low power operation, reducing the leakage current, and increasing the response speed.

As not only the gate additional electrode BG1 of the first transistor T1 but also the gate additional electrodes BG4 and BG6 of the fourth and sixth transistors T4 and T6 are included in the lower gate conductive layer LGCDL, the pattern density of the lower gate conductive layer LGCDL may be improved.

As the pattern density of the lower gate conductive layer LGCDL increases, the number of electrodes (patterns) that is used to determine the relative positions during the electrode pattern formation process increases, thereby improving the accuracy and precision of the process. In addition, this increased pattern density of the lower gate conductive layer LGCDL may prevent the first and second gate conductive layers GCDL1 and GCDL2 from being arranged excessively densely, thereby minimizing the occurrence of short circuits between adjacent electrodes.

In concluding the detailed description, those skilled in the art will appreciate that many variations and modifications can be made to the embodiments of the present disclosure without substantially departing from the principles of the present disclosure. Therefore, the disclosed embodiments of the present disclosure are used in a generic and descriptive sense only and not for purposes of limitation.

What is claimed is:

1. A display device comprising:
a substrate;
a circuit layer disposed on the substrate and comprising a light emitting pixel driver; and
a light emitting element layer disposed on the circuit layer and comprising a light emitting element, the light emitting element electrically connected to the light emitting pixel driver,
wherein the circuit layer comprises:
a first semiconductor layer;
a first gate conductive layer disposed on the first semiconductor layer;
a second gate conductive layer disposed on the first gate conductive layer;
a lower gate conductive layer disposed on the second gate conductive layer;
a second semiconductor layer disposed on the lower gate conductive layer; and
a third gate conductive layer disposed on the second semiconductor layer,
wherein the light emitting pixel driver comprises:
a first transistor comprising a gate electrode included in the third gate conductive layer, a channel portion, a first electrode and a second electrode included in the second semiconductor layer, and a gate additional electrode overlapping the channel portion; and
a second transistor comprising a gate electrode electrically connected to the gate electrode of the first transistor and included in the third gate conductive layer, a channel portion, a first electrode and a second electrode included in the second semiconductor layer, and a gate additional electrode overlapping the channel portion,
wherein the gate additional electrode of the first transistor is disposed on a same layer as the gate additional electrode of the second transistor.

2. The display device of claim 1, wherein the circuit layer further comprises a first source-drain conductive layer disposed on the third gate conductive layer,
the gate additional electrode of the first transistor is connected to the second electrode of the first transistor through a first contact hole,
the gate additional electrode of the second transistor is connected to the gate electrode of the second transistor through a second contact hole,
the first contact hole extends from the first source-drain conductive layer to the lower gate conductive layer, and
the second contact hole extends from the third gate conductive layer to the lower gate conductive layer.

3. The display device of claim 2, wherein a depth of the first contact hole is greater than a depth of the second contact hole.

4. The display device of claim 3, wherein an area of the first contact hole in a plan view is larger than an area of the second contact hole in the plan view.

5. The display device of claim 1, wherein the light emitting pixel driver further comprises a third transistor comprising a gate electrode included in the third gate conductive layer, a channel portion, a first electrode and a second electrode included in the second semiconductor layer, and a gate additional electrode overlapping the channel portion, and
the gate additional electrode of the third transistor is disposed on the same layer as the gate additional electrode of the first transistor and the gate additional electrode of the second transistor.

6. The display device of claim 1, wherein the light emitting pixel driver further comprises a fourth transistor comprising a first electrode, a second electrode and a channel portion electrically connected to the second electrode of the first transistor and included in the second semiconductor layer, a gate electrode included in the third gate conductive layer, and a gate additional electrode overlapping the channel portion, and
the gate additional electrode of the fourth transistor is disposed below the gate additional electrode of the second transistor.

7. The display device of claim 6, wherein a distance between the gate additional electrode of the second transistor and the channel portion of the second transistor is less than a distance between the gate additional electrode of the fourth transistor and the channel portion of the fourth transistor.

8. The display device of claim 7, wherein the gate additional electrode of the second transistor is connected to the gate electrode of the second transistor through a second contact hole,
the gate additional electrode of the fourth transistor is connected to the gate electrode of the fourth transistor through a third contact hole, and
a depth of the second contact hole is less than a depth of the third contact hole.

9. The display device of claim 8, wherein an area of the second contact hole in a plan view is smaller than an area of the third contact hole in the plan view.

10. The display device of claim 6, wherein the light emitting pixel driver further comprises a sixth transistor comprising a first electrode, a second electrode and a channel portion connected between the second electrode of the first transistor and the first electrode of the fourth transistor and included in the second semiconductor layer, a gate electrode included in the third gate conductive layer, and a gate additional electrode overlapping the channel portion, and
the gate additional electrode of the sixth transistor is disposed on the same layer as the gate additional electrode of the fourth transistor.

11. The display device of claim 1, wherein the light emitting pixel driver further comprises a fifth transistor comprising a first electrode, a second electrode and a channel portion electrically connected to the first electrode of the first transistor and included in the first semiconductor layer, and a gate electrode included in the first gate conductive layer.

12. The display device of claim 11, wherein the gate additional electrode of the second transistor is disposed on a layer different from the gate electrode of the fifth transistor.

13. The display device of claim 1, wherein the light emitting pixel driver further comprises a first capacitor comprising a second capacitor electrode electrically connected to the second electrode of the first transistor and included in the second gate conductive layer, and a first capacitor electrode overlapping the second capacitor electrode and included in the first gate conductive layer.

14. The display device of claim 13, wherein the gate additional electrode of the second transistor is disposed on a layer different from the first capacitor electrode and the second capacitor electrode of the first capacitor.

15. The display device of claim 1, wherein the light emitting pixel driver further comprises a second capacitor comprising a third capacitor electrode electrically connected to the second electrode of the first transistor and included in the second gate conductive layer, and a fourth capacitor electrode overlapping the third capacitor electrode and included in the first gate conductive layer.

16. The display device of claim 15, wherein the gate additional electrode of the second transistor is disposed on a layer different from the third capacitor electrode and the fourth capacitor electrode of the second capacitor.

17. The display device of claim 15, wherein the light emitting pixel driver further comprises a seventh transistor comprising a first electrode, a second electrode and a channel portion electrically connected to the fourth capacitor electrode of the second capacitor and included in the second semiconductor layer, and a gate electrode included in the third gate conductive layer.

18. The display device of claim 1, wherein the light emitting pixel driver further comprises a fourth transistor comprising a first electrode, a second electrode and a channel portion electrically connected to the second electrode of the first transistor and included in the second semiconductor layer, a gate electrode included in the third gate conductive layer, and a gate additional electrode overlapping the channel portion, and
the gate additional electrode of the fourth transistor is disposed on the same layer as the gate additional electrode of the second transistor.

19. The display device of claim 18, wherein the light emitting pixel driver further comprises a sixth transistor comprising a first electrode, a second electrode and a channel portion connected between the second electrode of the first transistor and the first electrode of the fourth transistor and included in the second semiconductor layer, a gate electrode included in the third gate conductive layer, and a gate additional electrode overlapping the channel portion, and
the gate additional electrode of the sixth transistor is disposed on the same layer as the gate additional electrode of the fourth transistor.

20. An electronic device comprising:
a display device displaying an image;
a lower cover located below the display device; and
a cover window located on the display device,
wherein the display device comprises:
a substrate;
a circuit layer disposed on the substrate and comprising a light emitting pixel driver; and
a light emitting element layer disposed on the circuit layer and comprising a light emitting element, the light emitting element electrically connected to the light emitting pixel driver,
wherein the circuit layer comprises:
a first semiconductor layer;
a first gate conductive layer disposed on the first semiconductor layer;
a second gate conductive layer disposed on the first gate conductive layer;
a lower gate conductive layer disposed on the second gate conductive layer;
a second semiconductor layer disposed on the lower gate conductive layer; and
a third gate conductive layer disposed on the second semiconductor layer,
wherein the light emitting pixel driver comprises:
a first transistor comprising a gate electrode included in the third gate conductive layer, a channel portion, a first electrode and a second electrode included in the second semiconductor layer, and a gate additional electrode overlapping the channel portion; and
a second transistor comprising a gate electrode electrically connected to the gate electrode of the first transistor and included in the third gate conductive layer, a channel portion, a first electrode and a second electrode included in the second semiconductor layer, and a gate additional electrode overlapping the channel portion,
wherein the gate additional electrode of the first transistor is disposed on a same layer as the gate additional electrode of the second transistor.
